(19) United States
(12) Patent Application Publication
(10) Pub. No.: US 2025/0267921 A1
(43) Pub. Date: Aug. 21, 2025

(54) SEMICONDUCTOR DEVICE WITH DUAL SILICIDE STRUCTURE AND METHODS THEREOF

(71) Applicant: Taiwan Semiconductor Manufacturing Company, Ltd., Hsin-Chu (TW)

(72) Inventors: I-Wen Wu, Hsinchu City (TW); Jui-Ping Lin, Hsinchu (TW); Po-Yu Huang, Hsinchu (TW); Chen-Ming Lee, Yangmei City (TW); Fu-Kai Yang, Hsinchu City (TW); Mei-Yun Wang, Chu-Pei City (TW)

(21) Appl. No.: 18/442,358

(22) Filed: Feb. 15, 2024

(51) Int. Cl. H01L 21/8238; H01L 21/285; H01L 27/092; H01L 29/45

(52) U.S. Cl. CPC H10D 84/038; H01L 21/28518; H10D 64/62; H10D 84/017; H10D 84/0186; H10D 84/0188; H10D 84/0193; H10D 84/853

(57) ABSTRACT

The present disclosure provides a semiconductor device and a method of forming the same. A method according to one embodiment of the present disclosure include forming a first fin in a first device region and a second fin in a second device region, forming a first epitaxial feature on the first fin and a second epitaxial feature on the second fin, depositing an etch stop layer covering the first epitaxial feature and the second epitaxial feature, depositing a first metal layer over the etch stop layer in the second device region and over the first epitaxial feature, forming a first silicide layer from the first metal layer and the first epitaxial feature, depositing a second metal layer over the first silicide layer in the first device region and over the second epitaxial feature, and forming a second silicide layer from the second metal layer and the second epitaxial feature.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

Such scaling down has also increased the complexity of processing and manufacturing ICs and, for these advances to be realized, similar developments in IC processing and manufacturing are needed. For instance, silicide structures are employed to reduce contact resistances between source/drain epitaxial features and source/drain contacts in semiconductor devices. Typically, the same silicide structure is implemented in both n-type and p-type transistors. However, this approach presents challenges to advance device performance in modern technology nodes. The differences between n-type and p-type transistors require separate optimizations for each. Therefore, although existing silicide technologies are generally adequate for their intended purposes, they are not satisfactory in every aspect.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a flowchart of a method for forming a semiconductor device, according to one or more aspects of the present disclosure.

FIG. 2 illustrates a perspective view of a workpiece during a fabrication process according to the method of FIG. 1, according to one or more aspects of the present disclosure.

FIGS. 3, 4, 5, 6, 7, 8, 9, 10, 11, 12, 13, 14, 15, 16, 17, 18, 19, 20, 21, 22, 23, 24, 25, 26, and 27 illustrate fragmentary cross-sectional views of a workpiece during a fabrication process according to the method of FIG. 1, according to one or more aspects of the present disclosure.

FIG. 28 illustrates a flowchart of another method for forming a semiconductor device, according to one or more aspects of the present disclosure.

FIGS. 29, 30, 31, 32, 33, 34, 35, 36, 37, 38, 39, 40, 41, 42, 43, 44, 45, and 46 illustrate fragmentary cross-sectional views of a workpiece during a fabrication process according to another method of FIG. 28, according to one or more aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art. Still further, the present disclosure may repeat reference numerals and/or letters in the various examples. This repetition is for the purpose of simplicity and clarity and does not in itself dictate a relationship between the various embodiments and/or configurations discussed.

The present disclosure is generally related to ICs and semiconductor devices and methods of forming the same. More particularly, the present disclosure is related to ICs and semiconductor devices with dual silicide structures. Silicide structures have been employed in ICs and semiconductor devices in order to reduce the contact resistances between contact features and epitaxial features developed in source/drain regions (also referred to as source/drain epitaxial features or source/drain features). Source/drain region(s) may refer to a source or a drain, individually or collectively dependent upon the context.

In a typical manufacturing flow the same silicide structure may be implemented in both n-type and p-type transistors. However, since source/drain features in n-type and p-type transistors are implanted with dopants of different conductivity types, such difference warrants developing one silicide structure for n-type transistors and one different silicide structure for p-type transistors, which are referred to as dual silicide structures. The dual silicide structures allow the silicide structures in n-type and p-type transistors to be individually optimized to further enhance transistor performance. For example, different work function metals (such as p-type work function metals and n-type work function metals) may be used for p-type transistors and n-type transistors, respectively. These work function metals interact with the respective materials of the source/drain features to form silicide features with different compositions for different types of transistors. As such, the Schottky barrier height is reduced and the contact resistances are accordingly reduced.

The details of the structure and fabrication methods of the present disclosure are described below in conjunction with the accompanied drawings, which illustrate a process of making a multi-gate device, according to some embodiments. As IC technologies progress towards smaller nodes, multi-gate metal-oxide-semiconductor field effect transistor (multi-gate MOSFET, or multi-gate devices) have been introduced to improve gate control by increasing gate-channel coupling, reducing off-state current, and reducing short-channel effects (SCEs). A multi-gate device generally refers to a device having a gate structure, or portion thereof, disposed over more than one side of a channel region. Fin-like field effect transistors (FinFETs) and multi-bridge-channel (MBC) transistors are examples of multi-gate devices that have become popular and promising candidates for high performance and low leakage applications. A FinFET has an elevated channel wrapped by a gate on more than one side (for example, the gate wraps a top and sidewalls of a “fin” of semiconductor material extending from a substrate). An MBC transistor has a gate structure that can extend, partially or fully, around a channel region to provide access to the channel region on two or more sides. Because its gate structure surrounds the channel regions, an MBC transistor may also be referred to as a surrounding gate transistor (SGT) or a gate-all-around (GAA) transistor. It is appreciated that although some embodiments in the present disclosure illustrate formation of FinFETs as examples of multi-gate transistors, these examples are provided for illustrative purpose only and one of ordinary skill in the art would realize the present disclosure also contemplates the formation of MBC transistors (e.g., SGT transistors or GAA transistors).

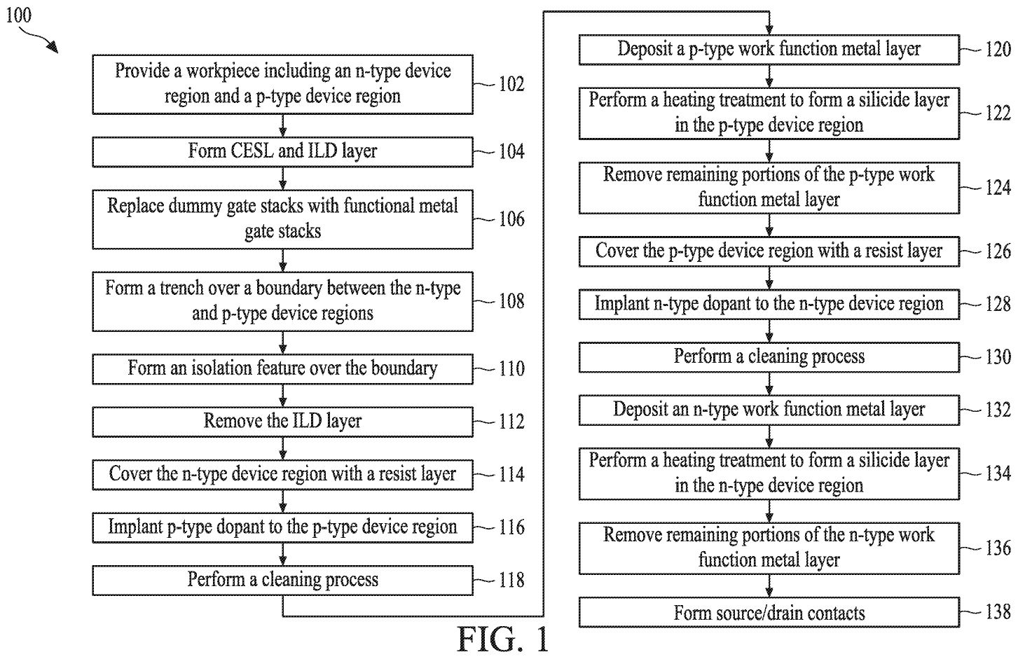

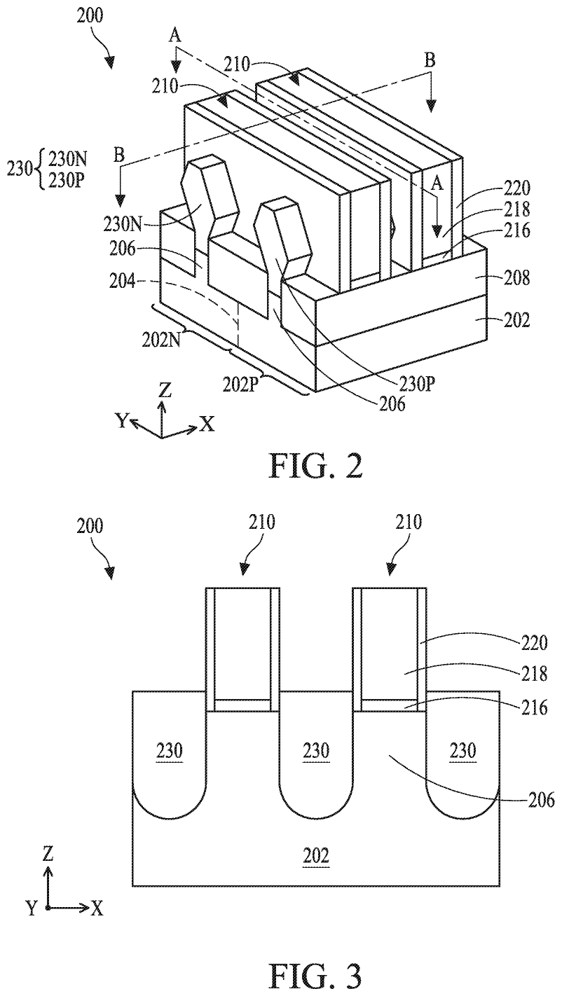

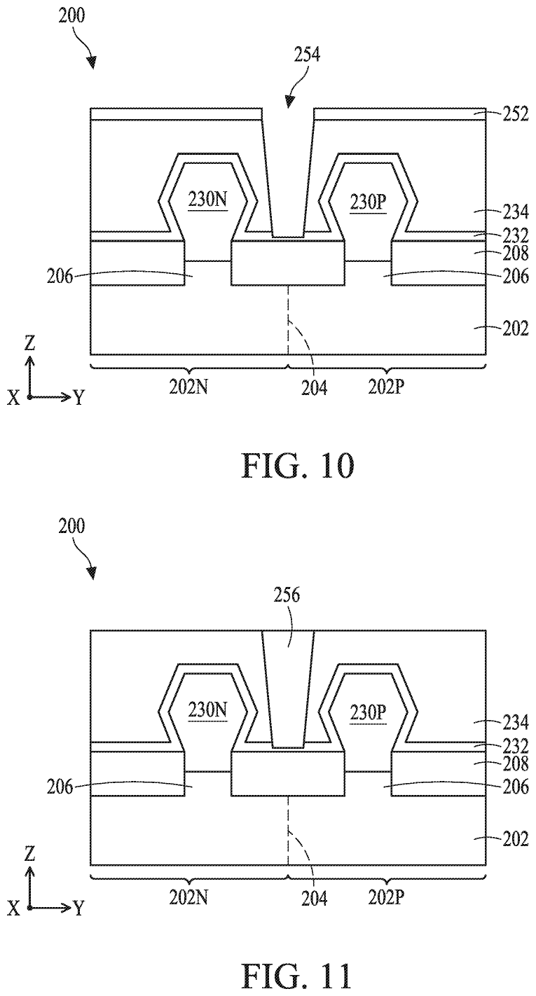

The various aspects of the present disclosure will now be described in more detail with reference to the figures. In that regard, FIG. 1 is a flowchart illustrating a method 100 of forming a semiconductor device from a workpiece according to embodiments of the present disclosure. Method 100 is merely an example and is not intended to limit the present disclosure to what is explicitly illustrated in method 100. Additional steps can be provided before, during and after method 100, and some steps described can be replaced, eliminated, or moved around for additional embodiments of the method. Not all steps are described herein in detail for reasons of simplicity. Method 100 is described below in conjunction with FIGS. 2-27, which are fragmentary cross-sectional views of workpiece 200 at different stages of fabrication according to embodiments of the method 100 in FIG. 1. Because the workpiece 200 will be fabricated into a semiconductor device, the workpiece 200 may be referred to herein as a semiconductor device 200 as the context requires. For avoidance, the X, Y and Z directions in figures are perpendicular to one another. Throughout the present disclosure, like reference numerals denote like features, unless otherwise excepted.

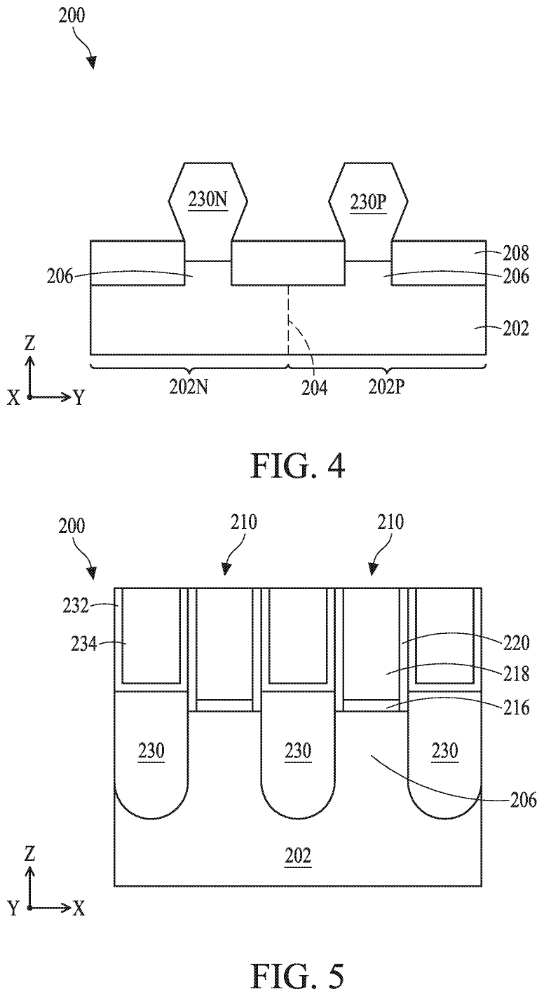

Referring to FIG. 1 and FIGS. 2-4, method 100 includes a block 102 where a workpiece 200 is received (or provided). FIG. 2 is a perspective view of an embodiment of the workpiece 200, FIG. 3 is a cross-sectional view along the B-B line in FIG. 2, and FIG. 4 is a cross-sectional view along the A-A line in FIG. 2. Particularly, the A-A line is cut into source/drain regions for transistors in the workpiece 200, and the B-B line is cut along the lengthwise direction of a channel region for transistors in the workpiece 200.

The workpiece 200 includes a substrate 202. The substrate 202 may comprise an elementary (single element) semiconductor, such as silicon, germanium, and/or other suitable materials; a compound semiconductor, such as silicon carbide, gallium arsenic, gallium phosphide, indium phosphide, indium arsenide, indium antimonide, and/or other suitable materials; an alloy semiconductor such as SiGe, GaAsP, AlInAs, AlGaAs, GaInAs, GaInP, GaInAsP, and/or other suitable materials. The substrate 202 may be a single-layer material having a uniform composition. Alternatively, the substrate 202 may include multiple material layers having similar or different compositions suitable for IC device manufacturing. In one example, the substrate 202 may be a silicon-on-insulator (SOI) substrate having a semiconductor silicon layer formed on a silicon oxide layer. In another example, the substrate 202 may include a conductive layer, a semiconductor layer, a dielectric layer, other layers, or combinations thereof. In one example, the substrate 202 is a silicon substrate, such as a silicon wafer.

The substrate 202 may include various doping configurations depending on design requirements as is known in the art. In embodiments where the semiconductor device is p-type, an n-type doping profile (i.e., an n-type well or n-well) may be formed on the substrate 202. In some implementations, the n-type dopant for forming the n-type well may include phosphorus (P) or arsenide (As). In embodiments where the semiconductor device is n-type, a p-type doping profile (i.e., a p-type well or p-well) may be formed on the substrate 202. In some implementations, the p-type dopant for forming the p-type well may include boron (B) or gallium (Ga). The suitable doping may include ion implantation of dopants and/or diffusion processes. In the illustrated embodiment, the substrate 202 includes a p-type device region 202P (where p-type devices such as p-type transistors are formed) and an n-type device region 202N (where n-type devices such as n-type transistors are formed). The dashed line 204 represents a boundary between the p-type device region 202P and the n-type device region 202N in the substrate 202 (e.g., a boundary between an n-well and a p-well in the substrate 202).

The p-type device region 202P and n-type device region 202N each include three-dimensional active regions 206 on the substrate 202. The active regions 206 are elongated fin-like structures that protrude upwardly out of the substrate 202 (e.g. along the Z direction). As such, the active regions 206 may be interchangeably referred to as fin active regions 206, fins 206, or fin-shape structures 206 hereinafter. In some embodiments, the fins 206 are formed from patterning the substrate 202. The fins 206 may be patterned from the substrate 202 using a lithography process and an etch process. The lithography process may include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etch process may include dry etching (e.g., RIE etching), wet etching, and/or other etching methods. The etch process forms trenches defining the fins 206. In some implementations, double-patterning or multi-patterning processes may be used to define fin-shape structures that have, for example, pitches smaller than what is otherwise obtainable using a single, direct photolithography process. For example, in one embodiment, a material layer is formed over a substrate and patterned using a photolithography process. Spacers are formed alongside the patterned material layer using a self-aligned process. The material layer is then removed, and the remaining spacers, or mandrels, may then be used to pattern the fins 206 by etching a top portion of the substrate 202.

The workpiece 200 further includes isolation structure 208 over the substrate 202. The isolation structure 208 electrically separate various components of the workpiece 200 (such as fins 206). The isolation structure 208 may include silicon oxide, silicon nitride, silicon oxynitride, other suitable isolation material (for example, including silicon, oxygen, nitrogen, carbon, or other suitable isolation constituent), or combinations thereof. The isolation structure 208 can include different features, such as shallow trench isolation (STI) features and/or deep trench isolation (DTI) features. In an embodiment, the isolation structure 208 can be formed by filling the trenches between fins 206 with insulator material (for example, by using a CVD process or a spin-on glass process), performing a chemical mechanical polishing (CMP) process to remove excessive insulator material and/or planarize a top surface of the insulator material layer, and etching back the insulator material layer to form the isolation structure 208. In some embodiments, the isolation structure 208 include multiple dielectric layers, such as a silicon nitride layer disposed over a thermal oxide liner layer.

The workpiece 200 also includes dummy gate stacks 210 formed over channel regions of the fins 206. In some embodiments, a gate replacement process (or gate-last process) is adopted where the dummy gate stacks 210 serve as a placeholder to undergo various processes and are to be removed and replaced by functional metal gate structures. Other processes and configuration are possible. In some embodiments, the dummy gate stacks 210 are formed over the fins 206 and the fins 206 may be divided into channel regions underlying the dummy gate stacks 210 and source/drain regions that do not underlie the dummy gate stacks 210. The channel regions are adjacent the source/drain regions. In the illustrated embodiment, the fins 206 are oriented lengthwise along the X direction, the dummy gate stacks 210 are oriented lengthwise along the Y direction, and each channel region is disposed between two source/drain regions along the X direction.

The dummy gate stack 210 may include a dummy dielectric layer 216 and a dummy electrode layer 218. In some embodiments, the dummy dielectric layer 216 may be formed on the fins 206 using a chemical vapor deposition (CVD) process, an ALD process, an oxygen plasma oxidation process, or other suitable processes. In some instances, the dummy dielectric layer 216 may include silicon oxide. Thereafter, the dummy electrode layer 218 may be deposited over the dummy dielectric layer 216 using a CVD process, an ALD process, or other suitable processes. In some instances, the dummy electrode layer 218 may include polysilicon. The dummy electrode layer 218 and the dummy dielectric layer 216 may then be patterned to form the dummy gate stacks 210. For example, the patterning process may include a lithography process (e.g., photolithography or e-beam lithography) which may further include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etching process may include dry etching (e.g., RIE etching), wet etching, and/or other etching methods.

The workpiece 200 also includes a gate spacer layer 220 deposited over the dummy gate stacks 210. In some embodiments, the gate spacer layer 220 is deposited conformally over the workpiece 200, including over top surface and sidewalls of the dummy gate stack 210. The term “conformally” may be used herein for ease of description of a layer having substantially uniform thickness over various regions. The gate spacer layer 220 may be a single layer or a multi-layer. The at least one layer in the gate spacer layer 220 may include silicon carbonitride, silicon oxycarbide, silicon oxycarbonitride, or silicon nitride. The gate spacer layer 220 may be deposited over the dummy gate stack 210 using processes such as, a CVD process, a subatmospheric CVD (SACVD) process, an ALD process, or other suitable process. In one embodiment, the gate spacer layer 220 includes a first layer and a second layer disposed over the first layer. The first layer may include silicon oxynitride and the second layer may include silicon nitride.

The p-type device region 202P and n-type device region 202N each also include source/drain features 230 formed over the fins 206. For example, the p-type device region 202P includes p-type source/drain feature 230P on both sides of the dummy gate stack 210 (such as in or on source/drain recesses); and the n-type device region 202N includes n-type source/drain feature 230N on both sides of the dummy gate stack 210 (such as in or on source/drain recesses). Source/drain recesses may be formed by recessing source/drain regions of the fins 206. In some embodiments, the source/drain regions that are not covered by the dummy gate stacks 210 and the gate spacer layer 220 are etched by a dry etch or a suitable etching process to form the source/drain recesses 228. In the illustrated embodiment, the fins 206 are recessed below a top surface of the isolation structure 208 in the source/drain regions. In some embodiments, the source/drain features 230 may include epitaxial layers (or epi-layers) that are epitaxially grown on the fins 206. In some embodiments, the source/drain features 230 each include a semiconductor material. For example, p-type source/drain feature 230P may include silicon germanium (SiGe) and n-type source/drain feature 230N include silicon (Si) and/or silicon carbide (SiC). In some embodiments, the p-type source/drain feature 230P may include germanium (Ge) at a concentration equal to or less than 50% by atomic percentage. In some embodiments, the p-type source/drain feature 230P may include Ge at a concentration equal to or less than 40% by atomic percentage.

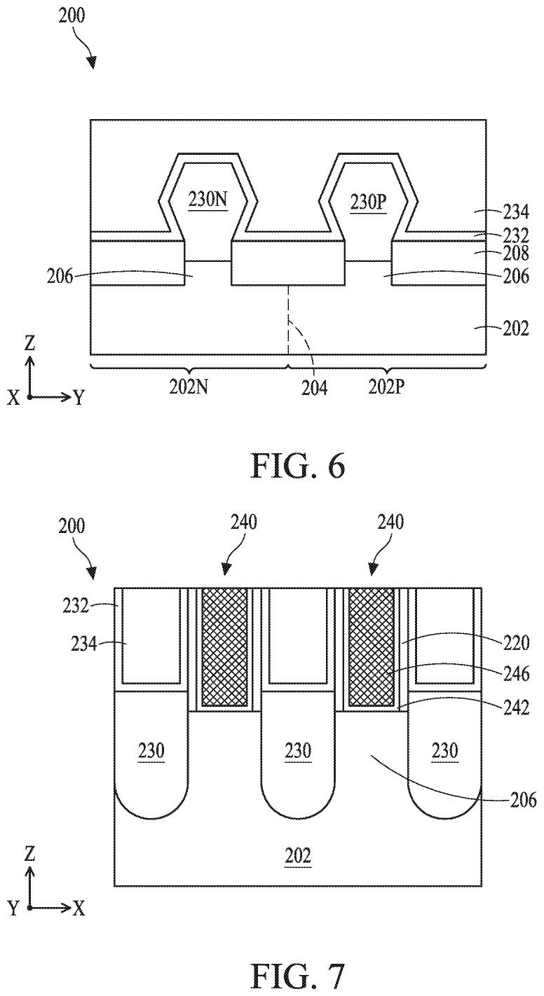

Referring to FIG. 1 and FIGS. 5-6, method 100 includes a block 104 where contact etch stop layer (CESL) 232 and interlayer dielectric (ILD) layer 234 are formed over the workpiece 200. The CESL 232 is formed prior to forming the ILD layer 234. The CESL 232 interposes between the isolation structure 208 and the ILD layer 234. The CESL 232 includes materials different from that of the ILD layer 234, and protects the features beneath the CESL 232 in subsequent etching operations. In some examples, the CESL 232 includes silicon nitride, silicon oxynitride, silicon carbonitride, silicon oxycarbonitride, and/or other materials known in the art. The CESL 232 may be conformally deposited by ALD, plasma-enhanced chemical vapor deposition (PECVD) process and/or other suitable deposition processes. The ILD layer 234 is then deposited over the CESL 232. In some embodiments, the ILD layer 234 includes materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The ILD layer 234 may be deposited by a PECVD process or other suitable deposition technique. In some embodiments, after formation of the ILD layer 234, the workpiece 200 may be annealed to improve integrity of the ILD layer 234. As shown in FIG. 6, the CESL 232 is conformally disposed directly on top and sidewall surfaces of the source/drain features 230N and 230P.

After the deposition of the CESL 232 and the ILD layer 234, the workpiece 200 may be planarized by a planarization process to expose the dummy gate stacks 210, such as shown in FIG. 5. For example, the planarization process may include a chemical mechanical planarization (CMP) process. Exposure of the dummy gate stacks 210 allows the removal of the dummy gate stacks 210 and the deposition of functional metal gate stacks.

Referring to FIGS. 1 and 7, method 100 includes a block 106 where the dummy gate stacks 210 are removed and replaced by metal gate stacks 240. In some embodiments, the removal of the dummy gate stacks 210 results in gate trenches over the channel regions. The removal of the dummy gate stacks 210 may include one or more etching processes that are selective to the material of the dummy gate stacks 210. For example, the removal of the dummy gate stacks 210 may be performed using as a selective wet etch, a selective dry etch, or a combination thereof that is selective to the dummy gate stacks 210. The method 100 may include further operations to form the metal gate stacks 240 within the gate trenches.

The metal gate stacks 240 include a gate dielectric layer 242 and a gate electrode layer 246 over the gate dielectric layer 242. In some embodiments, while not explicitly shown in the figures, the gate dielectric layer 242 includes an interfacial layer and a high-K gate dielectric layer. High-K dielectric materials, as used and described herein, include dielectric materials having a high dielectric constant, for example, greater than that of thermal silicon oxide (˜3.9). The interfacial layer may include a dielectric material such as silicon oxide, hafnium silicate, or silicon oxynitride. The interfacial layer may be formed by chemical oxidation, thermal oxidation, atomic layer deposition (ALD), chemical vapor deposition (CVD), and/or other suitable method. The high-K gate dielectric layer may include hafnium oxide. Alternatively, the high-K gate dielectric layer may include other high-K dielectric materials, such as titanium oxide (TiO₂), hafnium zirconium oxide (HfZrO), tantalum oxide (Ta₂O₅), hafnium silicon oxide (HfSiO₄), zirconium oxide (ZrO₂), zirconium silicon oxide (ZrSiO₂), lanthanum oxide (La₂O₃), aluminum oxide (Al₂O₃), zirconium oxide (ZrO), yttrium oxide (Y₂O₃), SrTiO₃ (STO), BaTiO₃ (BTO), BaZrO, hafnium lanthanum oxide (HfLaO), lanthanum silicon oxide (LaSiO), aluminum silicon oxide (AlSiO), hafnium tantalum oxide (HfTaO), hafnium titanium oxide (HfTiO), (Ba,Sr)TiO₃ (BST), silicon nitride (SiN), silicon oxynitride (SiON), combinations thereof, or other suitable material. The high-K gate dielectric layer may be formed by ALD, physical vapor deposition (PVD), CVD, oxidation, and/or other suitable methods.

The gate electrode layer 246 of the metal gate stacks 240 may include a single layer or alternatively a multi-layer structure, such as various combinations of a metal layer with a selected work function to enhance the device performance (work function metal layer), a liner layer, a wetting layer, an adhesion layer, a metal alloy or a metal silicide. By way of example, the gate electrode layer 246 may include titanium nitride (TiN), titanium aluminum (TiAl), titanium aluminum nitride (TiAlN), tantalum nitride (TaN), tantalum aluminum (TaAl), tantalum aluminum nitride (TaAlN), tantalum aluminum carbide (TaAlC), tantalum carbonitride (TaCN), aluminum (Al), tungsten (W), nickel (Ni), titanium (Ti), ruthenium (Ru), cobalt (Co), platinum (Pt), tantalum carbide (TaC), tantalum silicon nitride (TaSiN), copper (Cu), other refractory metals, or other suitable metal materials or a combination thereof. In various embodiments, the gate electrode layer 246 may be formed by ALD, PVD, CVD, e-beam evaporation, or other suitable process. In various embodiments, a CMP process may be performed to remove excessive metal, thereby providing a substantially planar top surface of the metal gate stacks 240. Upon conclusion of the operations at block 106, p-type transistors in the p-type device region 202P and n-type transistors in the n-type device region 202N are substantially formed.

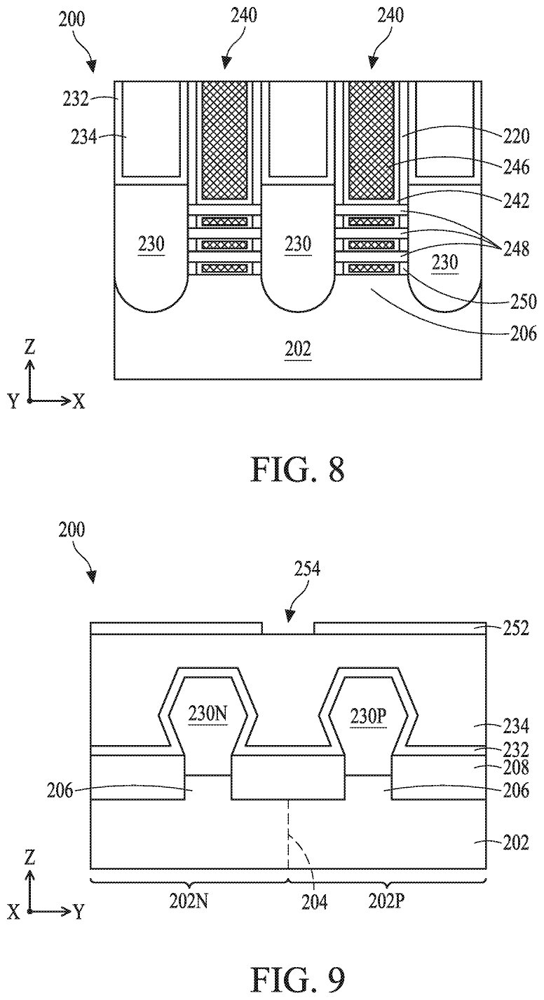

In some embodiment such as shown in FIG. 8, the workpiece 200 includes gate-all-around (GAA) transistors. Most of the features in FIGS. 7 and 8 are the same as or similar with like reference numerals denoting like features among the figures. Referring to FIG. 8, in this embodiment, the workpiece 200 further includes multiple nanosheets (or in the shapes of nanowires, rods, bars, or other suitable shapes) 248 of semiconductor materials (such as silicon) that are vertically stacked over the substrate 202 (along the Z direction) and horizontally connect the source/drain features 230. The nanosheets 248 are channel layers of the transistors and may be considered as part of the fins 206. Portions of the metal gate stacks 240 wrap around each of the channel layers 248. The workpiece 200 further includes inner spacers 250 horizontally between the source/drain features 230 and the portions of the metal gate stacks 240 and vertically between the channel layers 248. The inner spacers 250 may include metal oxides, silicon oxide, silicon oxycarbonitride, silicon nitride, silicon oxynitride, carbon-rich silicon carbonitride, or a low-k dielectric material. The metal oxides may include aluminum oxide, zirconium oxide, tantalum oxide, yttrium oxide, titanium oxide, lanthanum oxide, or other suitable metal oxide. While not explicitly shown, the inner spacers 250 may be a single layer or a multilayer.

Referring to FIG. 1 and FIGS. 9-10, method 100 includes a block 108 where patterned mask 252 is formed on the ILD layer 234 and the ILD layer 234 is subsequently etched through opening 254 defined in the patterned mask 252. The patterned mask 252 may be a patterned hard mask formed by lithography. For example, the patterning process may include a lithography process (e.g., photolithography or e-beam lithography) which may further include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etching process may include dry etching (e.g., RIE etching), wet etching, and/or other etching methods. In some embodiments, the patterned mask 252 include silicon oxide or silicon nitride. In some other embodiments, the patterned mask 252 is a patterned resist layer. The patterned mask 252 includes an opening 254. The opening 254 may be positioned between the p-type device region 202P and the n-type device region 202N. In the illustrated embodiment, the boundary line 204 is directly under the opening 254. Subsequently, an etch process is performed with the patterned mask 252 as the etch mask. The etch process etches the ILD layer 234 through the opening 254 defined in the patterned mask 252. The CESL 232 serves as an etch stop layer. The etch process extends the opening 254 downwardly in forming a trench until the CESL 232 is exposed. The trench is also numbered as 254. To ensure the ILD layer 234 is divided in half, the etch process may over-etch the CESL 232, such that a top surface of the CESL 232 is recessed and the trench 254 partially extends into the CESL 232. The trench 254 has a larger width at its opening and a smaller width at its bottom with slanted sidewalls.

Referring to FIGS. 1 and 11, method 100 includes a block 110 where isolation feature 256 is formed in the trench 254. The isolation feature 256 may include silicon, silicon nitride, silicon oxycarbide, silicon oxycarbonitride, or other suitable material. In an embodiment, the isolation feature 256 can be formed by filling the trench 254 between the ILD layer 234 with insulator material (for example, by using a CVD process or a spin-on glass process). After the deposition of insulator material, a planarization process, such as a CMP process, is performed to remove excessive insulator material. The patterned mask 252 may also be removed by the planarization process. The isolation feature 256 carries the shape of the trench 254 with a top surface with a larger width and a bottom surface with a smaller width. The bottom portion of the isolation feature 256 may be partially embedded in the CESL 232. In the illustrated embodiment, the isolation feature 256 is directly above the boundary line 204.

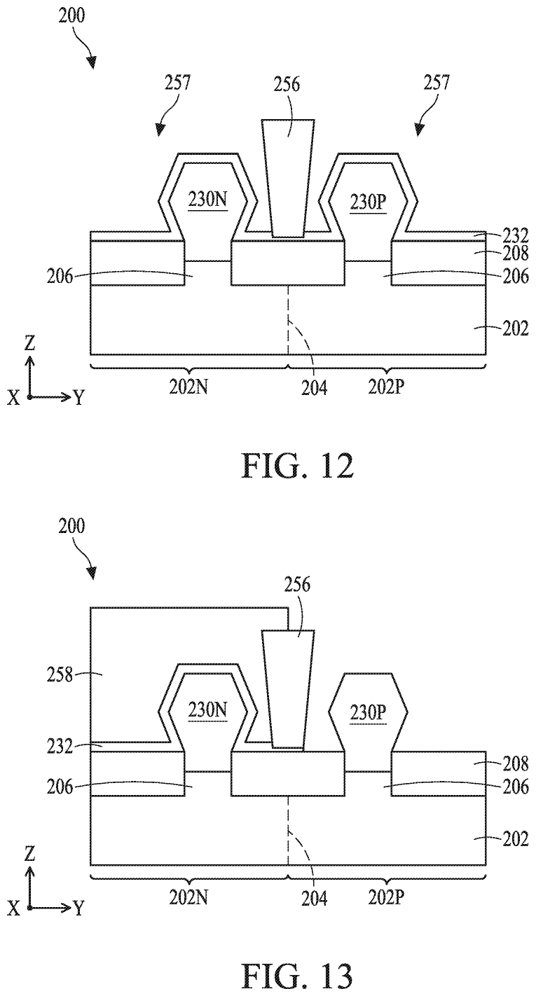

Referring to FIGS. 1 and 12, method 100 includes a block 112 where the ILD layer 234 is removed in an etch process. The removal of the ILD layer 234 creates two trenches 257 separated by the isolation feature 256. In some embodiments, an isotropic etch is performed to remove the ILD layer 234. An isotropic etch is more effective to remove portions of the ILD layer 234 under the slanted sidewalls of the isolation feature 256 and faceted sidewall surfaces of the source/drain features 230. The isotropic etch may be a dry etch, wherein the etching gas may be selected from CF₄, Cl₂, NF₃, SF₆, and combinations thereof. In alternative embodiments, a wet etch is then performed to remove the ILD layer 234. The wet etching may be performed, for example, using Tetra-Methyl Ammonium Hydroxide (TMAH), a potassium hydroxide (KOH) solution, or the like. In some exemplary embodiments, the TMAH solution has a concentration in a range between about 1 percent and about 30 percent. After the isotropic etch, the CESL 232 is exposed.

Referring to FIGS. 1 and 13, method 100 includes a block 114 where patterned resist layer 258 is formed to cover and protect the n-type device region 202N and the CESL 232 is removed from the p-type device region 202P. The p-type device region 202P is exposed in opening of the patterned resist layer 258. The patterned resist layer 258 may be formed by a photolithography process. An exemplary photolithography process may include processing steps of photoresist coating, soft baking, mask aligning, exposing, post-exposure baking, developing photoresist, and hard baking. The photolithography exposing process may also be implemented or replaced by other proper techniques such as maskless photolithography, electron-beam writing, ion-beam writing, and molecular imprint. In some embodiments, the patterned resist layer 258 is a bottom anti-reflective coating (BARC) layer. Subsequently, an etch process is performed to remove the CESL 232 from the p-type device region 202P. In some embodiments, the etch process may include dry etching (e.g., RIE etching), wet etching, and/or other etching methods. The etch process is selective to the dielectric material of the CESL 232, while the isolation feature 256, the isolation structure 208, and the p-type source/drain feature 230P remain substantially intact. The removal of the CESL 232 from the p-type device region 202P exposes the p-type source/drain feature 230P.

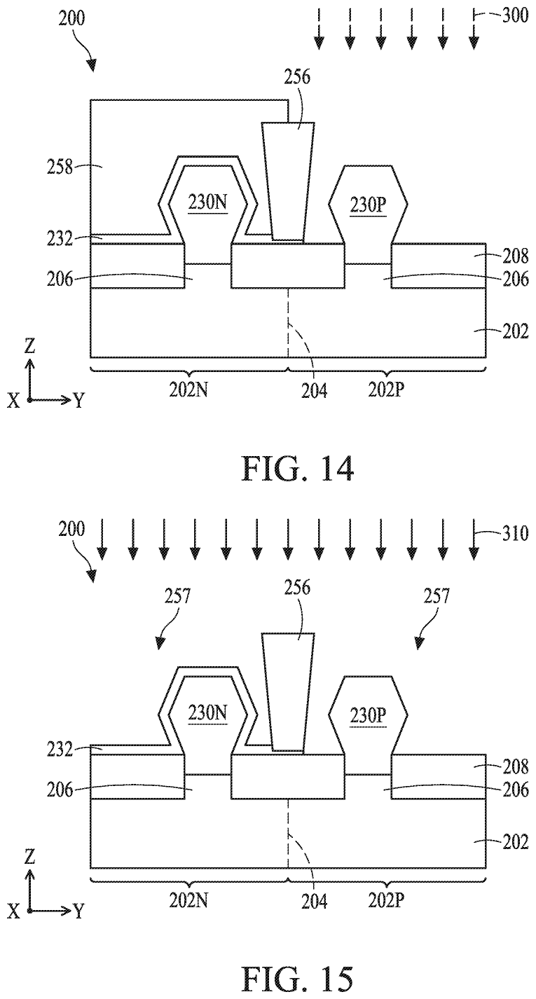

Referring to FIGS. 1 and 14, method 100 includes a block 116 where a p-type dopant is implanted into the p-type source/drain feature 230P in an implantation process 300. The patterned resist layer 258 acts as an implantation mask to substantially prevent the p-type dopant from being implanted into the n-type device region 202N. The p-type dopant may be boron, BF₂, indium, germanium, or a combination thereof. In some embodiments, the p-type source/drain feature 230P may be in-situ doped with a p-type dopant during the epitaxial process, then the implantation process 300 may be skipped. If the p-type source/drain feature 230P is not in-situ doped, the implantation process 300 (i.e., an ion implantation process) is performed to dope the p-type source/drain feature 230P with suitable p-type dopant. In some embodiments, the p-type source/drain feature 230P may have a dopant concentration of between about 10¹⁹ cm⁻³ and about 10²¹ cm⁻³. In an exemplary embodiment, the source/drain feature 230P after the p-type dopant implantation includes SiGeB. After the implantation process 300, the patterned resist layer 258 may be removed in a suitable etching process including wet etching, dry etching, reactive ion etching, ashing, and/or other suitable technique.

Referring to FIGS. 1 and 15, method 100 includes a block 118 where a cleaning process 310 is performed. The cleaning process 310 may include a dry clean, a wet clean, or a combination thereof. In some examples, the wet clean may include use of standard clean 1 (RCA SC-1, a mixture of deionized (DI) water, ammonium hydroxide, and hydrogen peroxide), standard clean 2 (RCA SC-2, a mixture of DI water, hydrochloric acid, and hydrogen peroxide), SPM (a sulfuric peroxide mixture), and/or hydrofluoric acid for oxide removal. The dry clean process may include helium (He) and hydrogen (H₂) treatment at a temperature between about 250° C. and about 550° C. and under a pressure between about 75 mTorr and about 155 mTorr. The hydrogen treatment may convert silicon on the surface to silane (SiH₄), which may be pumped out for removal. The cleaning process 310 may remove surface oxide and debris in order to ensure a clean semiconductor surface, which facilitates growth of silicide structure in subsequent processes.

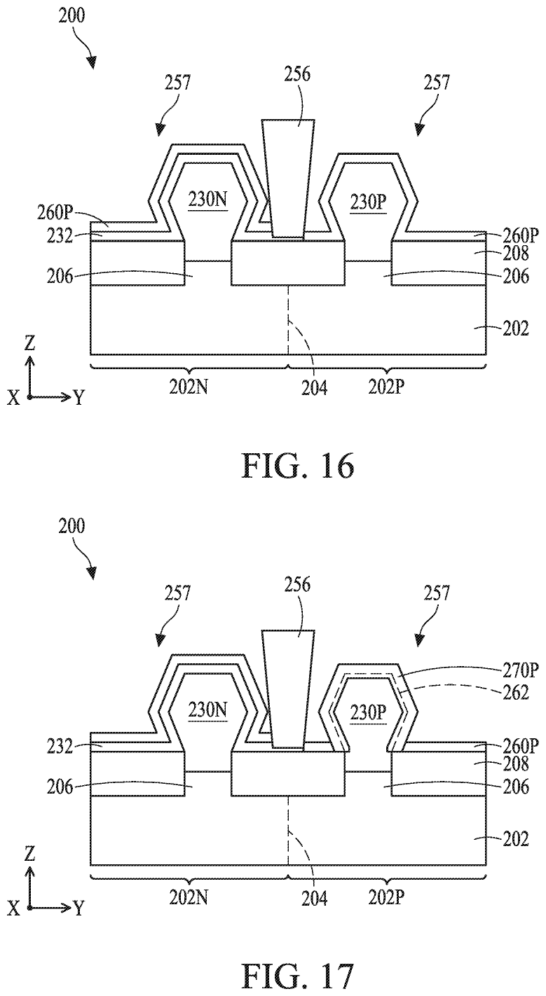

Referring to FIGS. 1 and 16, method 100 includes a block 120 where a metal layer 260P is formed over the p-type device region 202P and over the n-type device region 202N. The metal layer 260P directly contacts the p-type source/drain feature 230P, and directly contacts the CESL 232 over the n-type source/drain feature 230N. In other words, the metal layer 260P does not directly contact (or interface with) the n-type source/drain feature 230N. In some embodiments, the metal layer 260P includes a p-type work function metal. The metal layer 260P may also be referred to as the p-type work function metal layer 260P. P-type work function metals are metals that have work function values (e.g. amount of energy to remove an electron from the metal) greater (or more positive) than the Fermi level of the semiconductor. In some embodiments, the metal layer 260P includes nickel (Ni), platinum (Pt), palladium (Pd), vanadium (V), ruthenium (Ru), tantalum (Ta), titanium nitride, titanium silicon nitride, tantalum nitride, tungsten carbonitride, tungsten nitride, molybdenum (Mo), other suitable metal, or combinations thereof. In an exemplary embodiment, the metal layer 260P includes NiPt. The metal layer 260P may include a plurality of layers and may be deposited by ALD, CVD, PVD, and/or other suitable process. In some embodiments, the metal layer 260P is a conformal layer over the workpiece 200. That is, although not depicted in FIG. 16, the metal layer 260P may also be deposited on top and sidewall surfaces of the isolation feature 256. In some embodiments, the metal layer 260P has a thickness of about 5 nm to about 10 nm. If the thickness is too small, such as less than 5 nm, thermal agglomeration and/or discontinuous islanding may cause subsequently formed silicide layers to be non-uniform, thereby having reduced efficacy with respect to reducing contact resistances. If the thickness is too large, such as greater than 10 nm, it may unnecessarily take up valuable space that may be otherwise used by other important features of the transistors.

Referring to FIGS. 1 and 17, method 100 includes a block 122 where the workpiece 200 is subject to a heating treatment, such as an annealing treatment. In some embodiments, the heating treatment includes annealing the workpiece 200 at a temperature of about 300° C. to about 600° C. In some embodiments, the composition of the ambient gas, the composition of the purge gas, the flow rates of the ambient gas, the flow rate of the purge gas, the gas pressure in the chamber, as well as the temperature ramp-up rate, the temperature hold time, and the temperature range may all be adjusted in order to facilitate the chemical reaction that forms a silicide layer over the p-type source/drain feature 230P. Accordingly, the heating treatment induces a chemical reaction between the p-type source/drain feature 230P and the metal layer 260P. For example, the p-type work function metal of the metal layer 260P reacts with semiconductor atoms in the p-type source/drain feature 230P to form silicide layer 270P. In an exemplary embodiment, the metal layer 260P includes NiPt, and NiPt diffuses into an outer layer of the p-type source/drain feature 230P to react with Si in the p-type source/drain feature 230P. The reaction between NiPt and Si creates a layer of nickel platinum silicon (NiPtSi) as the silicide layer 270P. As a result, a thickness of the p-type source/drain feature 230P (such as along the Z direction) is reduced compared to before the heating treatment. The dashed line 262 represents the contour of the p-type source/drain feature 230P before the heating treatment, illustrating an outer layer of the p-type source/drain feature 230P is converted to a part of the silicide layer 270P. In some embodiments, the top surfaces of the p-type source/drain feature 230P and the n-type source/drain feature 230N are level before the heating treatment, and the top surface of the p-type source/drain features 230P is below the top surface of the n-type source/drain feature 230N after the heating treatment.

In some embodiments, the silicide layer 270P includes nickel silicon (NiSi), nickel platinum silicon (NiPtSi), other silicide materials, or combinations thereof. In some embodiments, the silicide layer 270P has a thickness of about 5 nm to about 10 nm. If the silicide layer thickness is too small, for example, less than 5 nm, the silicide layer may have limited efficacy in reducing the contact resistances. Furthermore, the silicide may become non-uniform where thermal agglomeration and discontinuous islanding occur. If the silicide layer thickness is too large, such as greater than 10 nm, a large portion of the source/drain material is consumed and may cause issues such as reduced speeds and leakages. After the heating treatment, the portion of the metal layer 260P in direct contact with the p-type source/drain feature 230P is consumed and converted to the silicide layer 270P, while other portions of the metal layer 260P in direction contact with dielectric surfaces of the isolation structure 208 and the CESL 232 do not participate in the chemical reaction. Therefore, the difference in material compositions between the silicide layer 270P and the remaining portions of the metal layer 260P allows the remaining portions of the metal layer 260P to be removed in subsequent processes.

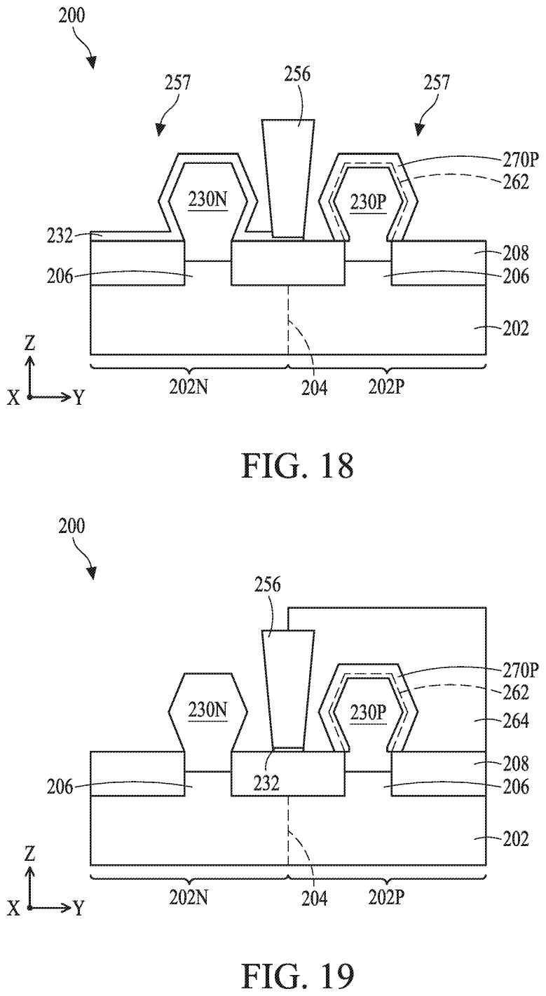

Referring to FIGS. 1 and 18, method 100 includes a block 124 where an etching process is employed to remove the remaining portions of the metal layer 260P from both the p-type device region 202P and the n-type device region 202N. The etching process is configured to remove the metal layer 260P without substantially etching the silicide layer 270P. In other words, this etching process is a selective etching process. As described above, this may be achieved because of the different material compositions in the silicide layer 270P and the metal layer 260P. Any suitable etching methods may be employed, such as wet etching methods. And any suitable etching chemical may be used. In some embodiments, the etching rate of the metal layer 260P in the etching chemical is at least 10 times greater than the etching rate of the silicide layer 270P in the same etching chemical. Accordingly, the silicide layer 270P is only minimally affected by the etching process. As a result of the etching process, the CESL 232 is exposed in the n-type device region 202N, while the top surface of the p-type source/drain feature 230P remains covered under the silicide layer 270P. Moreover, the silicide layer 270P is exposed in the p-type device region 202P.

Referring to FIGS. 1 and 19, method 100 includes a block 126 where patterned resist layer 264 is formed to cover and protect the p-type device region 202P and the CESL 232 is removed from the n-type device region 202N. The n-type device region 202N is exposed in opening of the patterned resist layer 264. The patterned resist layer 264 may be formed by a photolithography process. An exemplary photolithography process may include processing steps of photoresist coating, soft baking, mask aligning, exposing, post-exposure baking, developing photoresist, and hard baking. The photolithography exposing process may also be implemented or replaced by other proper techniques such as maskless photolithography, electron-beam writing, ion-beam writing, and molecular imprint. In some embodiments, the patterned resist layer 264 is a bottom anti-reflective coating (BARC) layer. Subsequently, an etch process is performed to remove the CESL 232 from the n-type device region 202N. In some embodiments, the etch process may include dry etching (e.g., RIE etching), wet etching, and/or other etching methods. The etch process is selective to the dielectric material of the CESL 232, while the isolation feature 256, the isolation structure 208, and the n-type source/drain feature 230N remain substantially intact. The removal of the CESL 232 from the n-type device region 202N exposes the n-type source/drain feature 230N. Moreover, the isolation feature 256 may protect a small portion of the CESL 232 directly thereunder from removal.

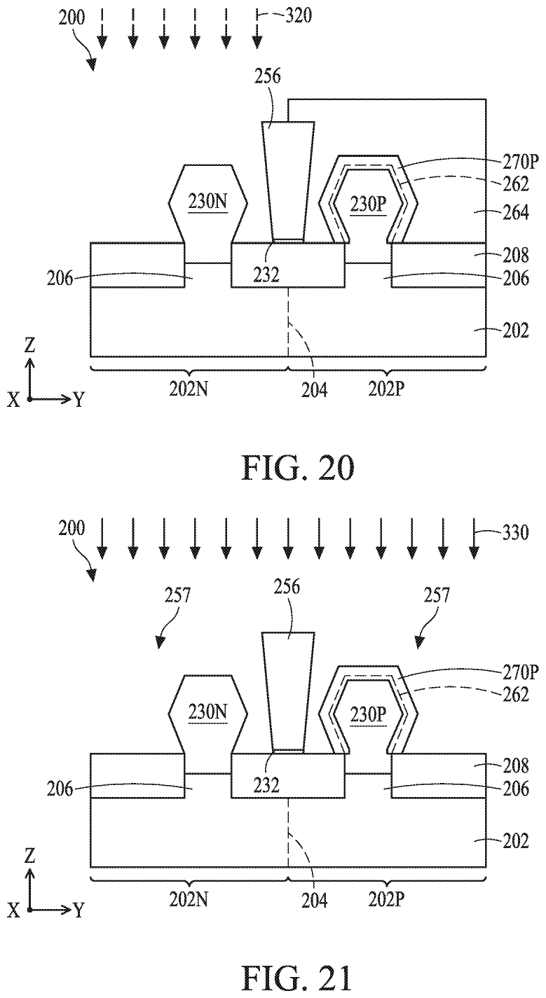

Referring to FIGS. 1 and 20, method 100 includes a block 128 where an n-type dopant is implanted into the n-type source/drain feature 230N in an implantation process 320. The patterned resist layer 264 acts as an implantation mask to substantially prevent the n-type dopant from being implanted into the p-type device region 202P. The n-type dopant may be phosphorus, arsenic, antimony, or a combination thereof. In some embodiments, the n-type source/drain feature 230N may be in-situ doped with an n-type dopant during the epitaxial process, then the implantation process 320 may be skipped. If the n-type source/drain feature 230N is not in-situ doped, the implantation process 320 (i.e., an ion implantation process) is performed to dope the n-type source/drain feature 230N with suitable n-type dopant. In some embodiments, the n-type source/drain feature 230N may have a dopant concentration of between about 10¹⁹ cm⁻³ and about 10²¹ cm⁻³. In an exemplary embodiment, the source/drain feature 230N after the n-type dopant implantation includes SiP. After the implantation process 320, the patterned resist layer 264 may be removed in a suitable etching process including wet etching, dry etching, reactive ion etching, ashing, and/or other suitable technique.

Referring to FIGS. 1 and 21, method 100 includes a block 130 where a cleaning process 330 is performed. The cleaning process 330 may include a dry clean, a wet clean, or a combination thereof. In some examples, the wet clean may include use of standard clean 1 (RCA SC-1, a mixture of deionized (DI) water, ammonium hydroxide, and hydrogen peroxide), standard clean 2 (RCA SC-2, a mixture of DI water, hydrochloric acid, and hydrogen peroxide), SPM (a sulfuric peroxide mixture), and/or hydrofluoric acid for oxide removal. The dry clean process may include helium (He) and hydrogen (H₂) treatment at a temperature between about 250° C. and about 550° C. and under a pressure between about 75 mTorr and about 155 mTorr. The hydrogen treatment may convert silicon on the surface to silane (SiH₄), which may be pumped out for removal. The cleaning process 330 may remove surface oxide and debris in order to ensure a clean semiconductor surface, which facilitates growth of silicide structure in subsequent processes.

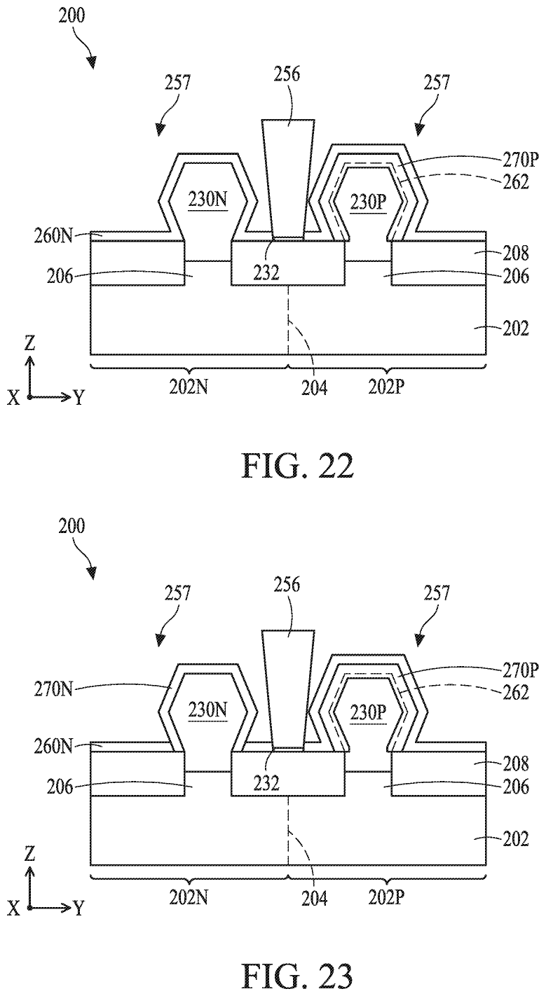

Referring to FIGS. 1 and 22, method 100 includes a block 132 where a metal layer 260N is formed over the n-type device region 202N and over the p-type device region 202P. The metal layer 260N directly contacts the n-type source/drain feature 230N, and directly contacts the silicide layer 270P over the p-type source/drain feature 230P. In other words, the metal layer 260N does not directly contact (or interface with) the p-type source/drain feature 230P. In some embodiments, the metal layer 260N includes an n-type work function metal. The metal layer 260N may also be referred to as the n-type work function metal layer 260N. N-type work function metals are metals that have work function values less (or lower) than the Fermi level of the semiconductor. The n-type work function metal may be any suitable n-type work function metals, such as titanium (Ti), aluminum (Al), ytterbium (Yb), silver (Ag), TaAl, TaAlC, TiAlN, TaC, TaCN, TaSiN, manganese (Mn), zirconium (Zr), other suitable metal, or combinations thereof. In an exemplary embodiment, the metal layer 260P includes Ti. The metal layer 260N may include a plurality of layers and may be deposited by ALD, CVD, PVD, and/or other suitable process. In some embodiments, the metal layer 260N is a conformal layer over the workpiece 200. That is, although not depicted in FIG. 16, the metal layer 260N may also be deposited on top and sidewall surfaces of the isolation feature 256. In some embodiments, the metal layer 260N has a thickness of about 5 nm to about 10 nm. If the thickness is too small, such as less than 5 nm, thermal agglomeration and/or discontinuous islanding may cause subsequently formed silicide layers to be non-uniform, thereby having reduced efficacy with respect to reducing contact resistances. If the thickness is too large, such as greater than 10 nm, it may unnecessarily take up valuable space that may be otherwise used by other important features of the transistors.

Referring to FIGS. 1 and 23, method 100 includes a block 134 where the workpiece 200 is subject to a heating treatment, such as an annealing treatment. In some embodiments, the heating treatment includes annealing the workpiece 200 at a temperature of about 300° C. to about 600° C. In some embodiments, the composition of the ambient gas, the composition of the purge gas, the flow rates of the ambient gas, the flow rate of the purge gas, the gas pressure in the chamber, as well as the temperature ramp-up rate, the temperature hold time, and the temperature range may all be adjusted in order to facilitate the chemical reaction that forms a silicide layer over the n-type source/drain feature 230N. Accordingly, the heating treatment induces a chemical reaction between the n-type source/drain feature 230N and the metal layer 260N. For example, the n-type work function metal of the metal layer 260N reacts with semiconductor atoms in the n-type source/drain feature 230N to form silicide layer 270N. In an exemplary embodiment, the metal layer 260N includes Ti, and Si atoms diffuse from the n-type source/drain feature 230N into the metal layer 260N to react with Ti in the metal layer 260N. The reaction between Ti and Si creates a layer of titanium silicon (TiSi) as the silicide layer 270N. Since Si atoms diffuse upwardly into the metal layer 260N, a thickness of the p-type source/drain feature 230P (such as along the Z direction) may be substantially maintained compared to before the heating treatment. That is, the top surface of the p-type source/drain features 230P may be below the top surface of the n-type source/drain feature 230N after the heating treatment, and the top surface of the silicide layer 270P may be below the top surface of the silicide layer 270N.

In some embodiments, the silicide layer 270P includes titanium silicon (TiSi), titanium aluminum silicon (TiAlSi), other silicide materials, or combinations thereof. In some embodiments, the silicide layer 270N has a thickness of about 5 nm to about 10 nm. If the silicide layer thickness is too small, for example, less than 5 nm, the silicide layer may have limited efficacy in reducing the contact resistances. Furthermore, the silicide may become non-uniform where thermal agglomeration and discontinuous islanding occur. If the silicide layer thickness is too large, such as greater than 10 nm, a large portion of the source/drain material is consumed and may cause issues such as reduced speeds and leakages. After the heating treatment, the portion of the metal layer 260N in direct contact with the n-type source/drain feature 230N is consumed and converted to the silicide layer 270N, while other portions of the metal layer 260N in direction contact with dielectric surfaces of the isolation structure 208 and silicide surfaces of the silicide layer 270P do not participate in the chemical reaction. Therefore, the difference in material compositions between the silicide layer 270N and the remaining portions of the metal layer 260N allows the remaining portions of the metal layer 260N to be removed in subsequent processes.

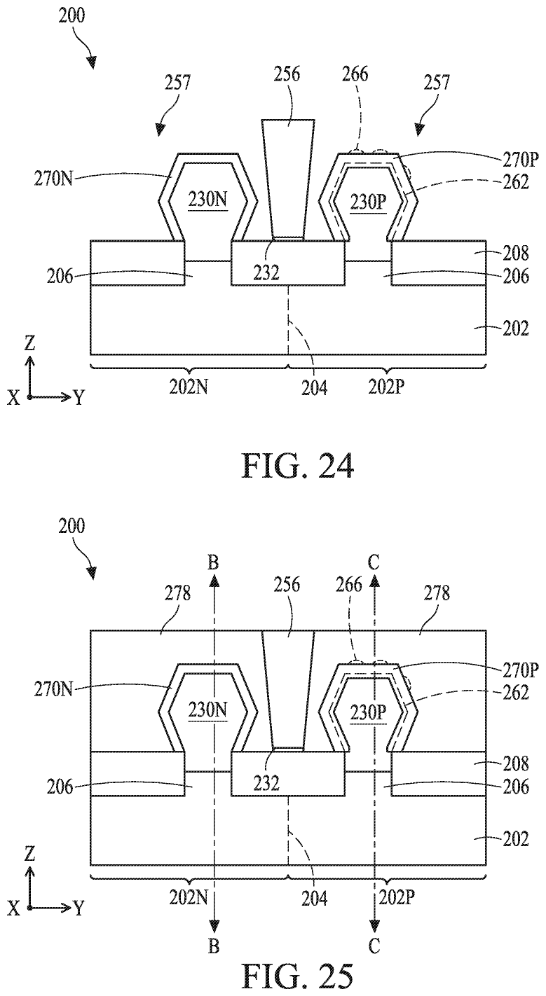

Referring to FIGS. 1 and 24, method 100 includes a block 136 where an etching process is employed to remove the remaining portions of the metal layer 260N from both the n-type device region 202N and the p-type device region 202P. The etching process is configured to remove the metal layer 260N without substantially etching the silicide layer 270N and the silicide layer 270P. In other words, this etching process is a selective etching process. As described above, this may be achieved because of the different material compositions in the silicide layers 270N, 270P and the metal layer 260N. Any suitable etching methods may be employed, such as wet etching methods. And any suitable etching chemical may be used. In some embodiments, the etching rate of the metal layer 260N in the etching chemical is at least 10 times greater than the etching rate of the silicide layers 270N, 270P in the same etching chemical. Accordingly, the silicide layers 270N, 270P is only minimally affected by the etching process. As a result of the etching process, the silicide layers 270N and 270P are exposed in the n-type device region 202N and the p-type device region 202P, respectively. Further, some residues of the metal layer 260N may remain on the top and sidewall surfaces of the silicide layer 270P. For example, in some embodiments the metal layer 260N includes Ti, and Ti-containing residues may remain as sporadic islands 266 on top and sidewall surfaces of the silicide layer 270P.

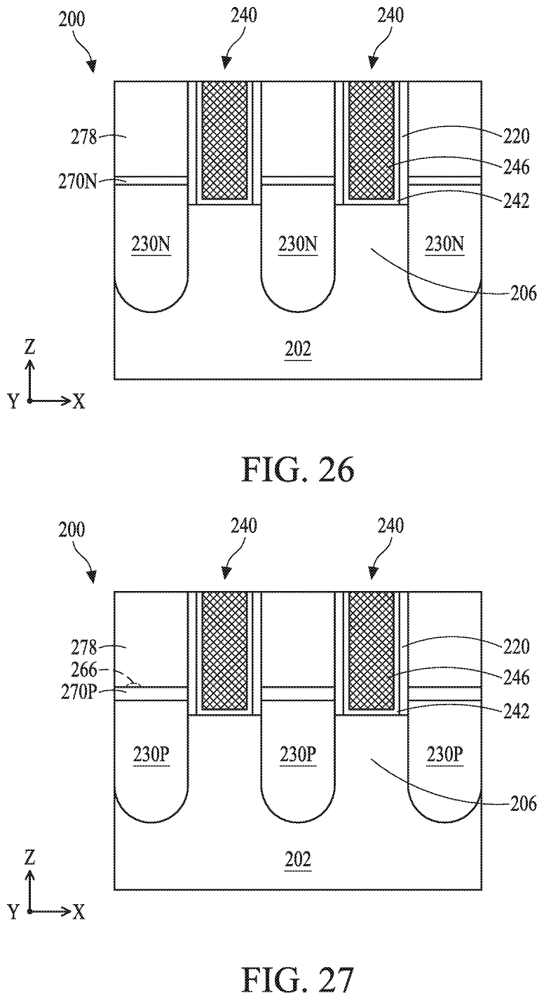

Referring to FIG. 1 and FIGS. 25-27, method 100 includes a block 138 where source/drain contacts 278 are formed over the silicide layers 270N and 270P. FIG. 26 is a cross-sectional view along the B-B line in FIG. 25, and FIG. 27 is a cross-sectional view along the C-C line in FIG. 25. Particularly, the B-B line is cut along the lengthwise direction of a fin 206 in the n-type device region 202N, and the C-C line is cut along the lengthwise direction of a fin 206 in the p-type device region 202P. The source/drain contacts 278 are formed in the remaining spaces of the trenches 257 such that they are entirely filled. Accordingly, the formation of the source/drain contacts is a self-aligned method that uses fewer photolithography steps and/or fewer hard mask layers. The source/drain contacts 278 may include a conductive barrier layer and a metal fill layer over the conductive barrier layer. The conductive barrier layer may include titanium (Ti), tantalum (Ta), tungsten (W), cobalt (Co), ruthenium (Ru), or a conductive nitride such as titanium nitride (TiN), titanium aluminum nitride (TiAlN), tungsten nitride (WN), tantalum nitride (TaN), or combinations thereof, and may be formed by CVD, PVD, ALD, and/or other suitable processes. The metal fill layer may include tungsten (W), cobalt (Co), molybdenum (Mo), ruthenium (Ru), nickel (Ni), copper (Cu), or other metals, and may be formed by CVD, PVD, ALD, plating, or other suitable processes. In some embodiments, the conductive barrier layer is omitted in the source/drain contacts 278. In some embodiments, a planarization process, such as a CMP process, performed to planarize the top surface of the workpiece 200 and expose the metal gate stacks 240. In the illustrated embodiment, the CESL 232 may be removed from the trenches 257 (except for the portion covered by the isolation feature 256), and the source/drain contacts 278 are in direct contact with the gate spacer layer 220. Further, as discussed above, the top surface of the silicide layer 270N may be above the top surface of the silicide layer 270P, and the top surface of the n-type source/drain feature 230N may be above the top surface of the p-type source/drain feature 230P. Moreover, in a top view of the workpiece 200, the isolation feature 256 extends continuously from a gate spacer layer 220 of a first metal gate stack 240 to a gate spacer layer 220 of a second metal gate stack 240 along the X direction. The isolation feature 256 separates the source/drain contact 278 in the n-type device region 202N from the source/drain contact 278 in the p-type device region 202P.

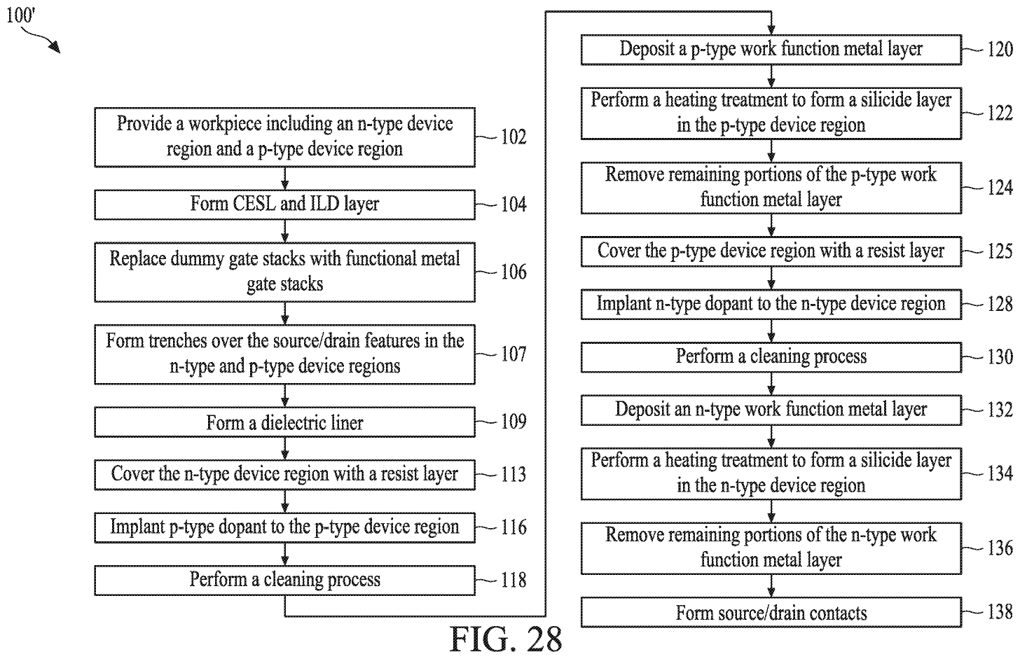

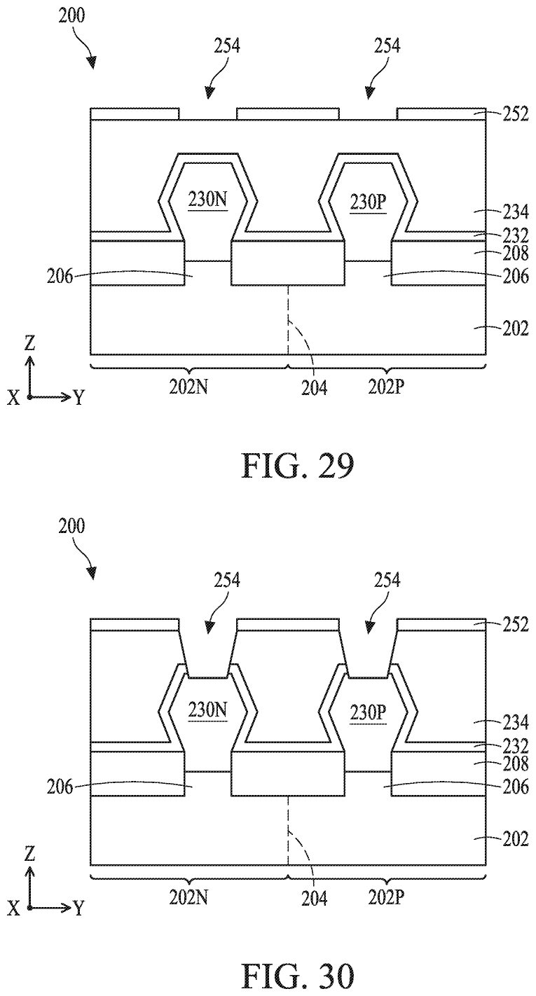

Reference is now made to FIG. 28, which is a flowchart illustrating a method 100′ of forming a semiconductor device from a workpiece according to some alternative embodiments of the present disclosure. Method 100′ is merely an example and is not intended to limit the present disclosure to what is explicitly illustrated in method 100′. Additional steps can be provided before, during and after method 100′, and some steps described can be replaced, eliminated, or moved around for additional embodiments of the method. Some aspects of the method 100′ are the same as the method 100, and will be briefly discussed below for reasons of simplicity. Other aspects of the method 100′ are different from the method 100, and will be described in more details. Method 100′ is described below in conjunction with FIGS. 29-46, which are fragmentary cross-sectional views of the workpiece 200 at different stages of fabrication according to embodiments of the method 100′ in FIG. 28.

The aspects of the operations at blocks 202, 204, and 206 of the method 100′ are substantially the same as those of the operations at blocks 202, 204, and 206 of the method 100 as discussed above with reference to FIGS. 2-8.

Referring to FIG. 28 and FIGS. 29-30, method 100′ includes a block 107 where patterned mask 252 is formed on the ILD layer 234 and the ILD layer 234 is subsequently etched through openings 254 defined in the patterned mask 252. The patterned mask 252 may be a patterned hard mask formed by lithography. For example, the patterning process may include a lithography process (e.g., photolithography or e-beam lithography) which may further include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etching process may include dry etching (e.g., RIE etching), wet etching, and/or other etching methods. In some embodiments, the patterned mask 252 include silicon oxide or silicon nitride. In some other embodiments, the patterned mask 252 is a patterned resist layer. The patterned mask 252 defines one opening 254 directly above the n-type source/drain feature 230N and one opening 254 directly above the p-type source/drain feature 230P. Subsequently, an etch process is performed with the patterned mask 252 as the etch mask. The etch process etches the ILD layer 234 through the openings 254 defined in the patterned mask 252. The etch process extends the openings 254 downwardly in forming trenches through the CESL 232, such that the source/drain features 230 are exposed in the trenches. The trenches are also numbered as 254. The etch process may over-etch the source/drain features 230, such that a top surface of each source/drain feature 230 is slightly recessed and the trench 254 partially extends into the source/drain features 230. The trenches 254 each have a larger width at its opening and a smaller width at its bottom with slanted sidewalls. Subsequently, the patterned mask 252 may be removed in a suitable etching process including wet etching, dry etching, reactive ion etching, ashing, and/or other suitable technique.

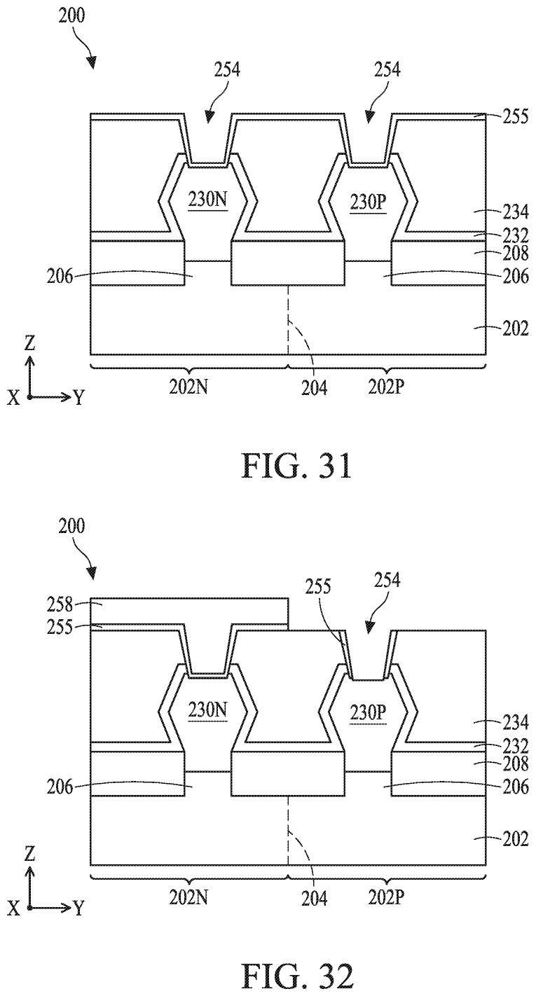

Referring to FIGS. 28 and 31, method 100′ includes a block 109 where a dielectric liner 255 is deposited on the workpiece 200. The dielectric liner 255 includes materials different from that of the ILD layer 234, and protects the ILD layer 234 from subsequent etching operations. Accordingly, the dielectric liner 255 functions as an etch stop layer. In some examples, the dielectric liner 255 includes silicon nitride, silicon oxynitride, silicon carbonitride, silicon oxycarbonitride, and/or other materials known in the art. The dielectric liner 255 may be conformally deposited by ALD, plasma-enhanced chemical vapor deposition (PECVD) process and/or other suitable deposition processes. In the illustrated embodiment, the dielectric liner 255 covers the top surface of the ILD layer 234 and covers the sidewall and bottom surfaces of the trenches 254. In some embodiments, the dielectric liner 255 has a thickness of about 4 nm to about 8 nm. If the thickness is too small, such as less than 4 nm, subsequent etching processes may etch through the dielectric liner 255 and cause etching loss to the ILD layer 234. If the thickness is too large, such as greater than 8 nm, it may unnecessarily take up valuable space that may be otherwise used by other important features of the transistors.

Referring to FIGS. 28 and 32, method 100′ includes a block 113 where patterned resist layer 258 is formed to cover and protect the n-type device region 202N and horizontal portions of the dielectric liner 255 are removed from the p-type device region 202P. The p-type device region 202P is exposed in opening of the patterned resist layer 258. The patterned resist layer 258 may be formed by a photolithography process. An exemplary photolithography process may include processing steps of photoresist coating, soft baking, mask aligning, exposing, post-exposure baking, developing photoresist, and hard baking. The photolithography exposing process may also be implemented or replaced by other proper techniques such as maskless photolithography, electron-beam writing, ion-beam writing, and molecular imprint. In some embodiments, the patterned resist layer 258 is a bottom anti-reflective coating (BARC) layer. Subsequently, an etching process is performed for breaking through, and removing the majority of, the horizontal portions of the dielectric liner 255. The etching process is also referred to as a breakthrough (BT) etching process. In some embodiments, the BT etching process may include an anisotropic dry etch process, or the like. In some embodiments where the dielectric liner 255 is formed of an oxide compound, the BT etch process is a reactive ion etch (RIE) process with etch process gases including CHF₃, Ar, CF₄, N₂, O₂, CH₂F₂, SF₃, the like, or a combination thereof. In the illustrated embodiment, as a result of the BT etching process, portions of the dielectric liner 255 remain on sidewalls of the trench 254 in the p-type device region 202P. Moreover, a recessed top surface of the p-type source/drain feature 230P is exposed in the trench 254.

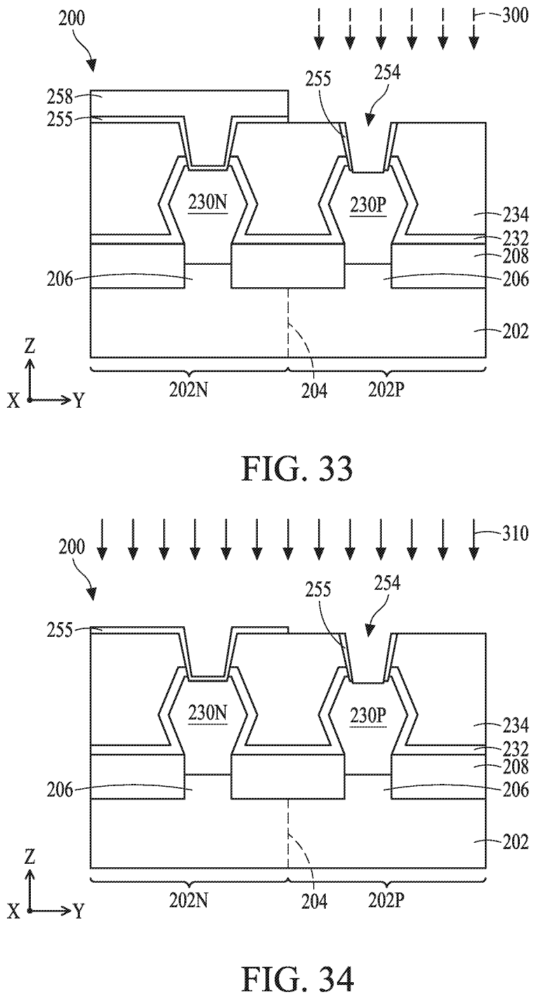

Referring to FIGS. 28 and 33, method 100′ includes a block 116 where a p-type dopant is implanted into the p-type source/drain feature 230P in an implantation process 300. The patterned resist layer 258 acts as an implantation mask to substantially prevent the p-type dopant from being implanted into the n-type device region 202N. The p-type dopant may be boron, BF₂, indium, germanium, or a combination thereof. In some embodiments, the p-type source/drain feature 230P may be in-situ doped with a p-type dopant during the epitaxial process, then the implantation process 300 may be skipped. If the p-type source/drain feature 230P is not in-situ doped, the implantation process 300 (i.e., an ion implantation process) is performed to dope the p-type source/drain feature 230P with suitable p-type dopant. In some embodiments, the p-type source/drain feature 230P may have a dopant concentration of between about 10¹⁹ cm⁻³ and about 10²¹ cm⁻³. In an exemplary embodiment, the source/drain feature 230P after the p-type dopant implantation includes SiGeB. After the implantation process 300, the patterned resist layer 258 may be removed in a suitable etching process including wet etching, dry etching, reactive ion etching, ashing, and/or other suitable technique.

Referring to FIGS. 28 and 34, method 100′ includes a block 118 where a cleaning process 310 is performed. The cleaning process 310 may include a dry clean, a wet clean, or a combination thereof. In some examples, the wet clean may include use of standard clean 1 (RCA SC-1, a mixture of deionized (DI) water, ammonium hydroxide, and hydrogen peroxide), standard clean 2 (RCA SC-2, a mixture of DI water, hydrochloric acid, and hydrogen peroxide), SPM (a sulfuric peroxide mixture), and/or hydrofluoric acid for oxide removal. The dry clean process may include helium (He) and hydrogen (H₂) treatment at a temperature between about 250° C. and about 550° C. and under a pressure between about 75 mTorr and about 155 mTorr. The hydrogen treatment may convert silicon on the surface to silane (SiH₄), which may be pumped out for removal. The cleaning process 310 may remove surface oxide and debris in order to ensure a clean semiconductor surface, which facilitates growth of silicide structure in subsequent processes.

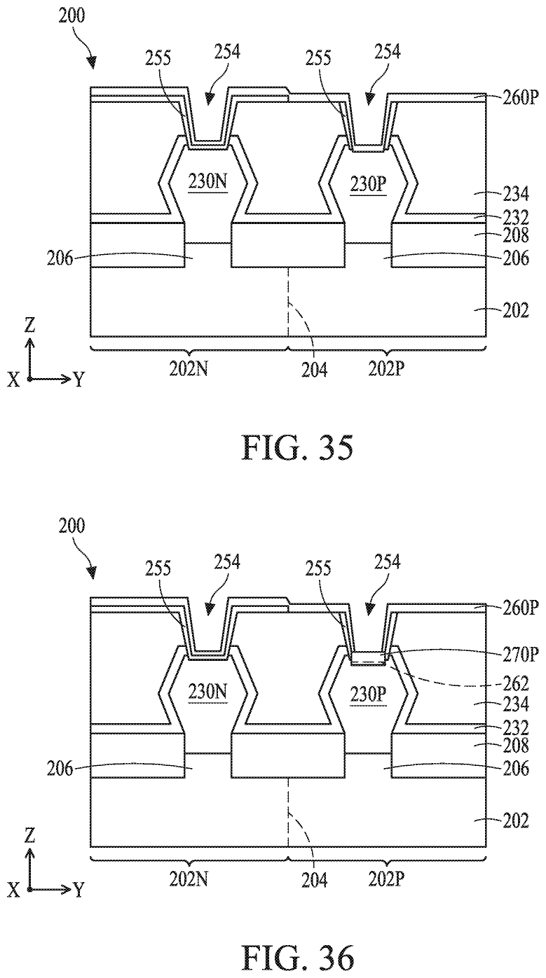

Referring to FIGS. 28 and 35, method 100′ includes a block 120 where a metal layer 260P is formed over the p-type device region 202P and over the n-type device region 202N. The metal layer 260P directly contacts the p-type source/drain feature 230P, and directly contacts the dielectric liner 255 over the n-type source/drain feature 230N. In other words, the metal layer 260P does not directly contact (or interface with) the n-type source/drain feature 230N. In some embodiments, the metal layer 260P includes a p-type work function metal. The metal layer 260P may also be referred to as the p-type work function metal layer 260P. P-type work function metals are metals that have work function values (e.g. amount of energy to remove an electron from the metal) greater (or more positive) than the Fermi level of the semiconductor. In some embodiments, the metal layer 260P includes nickel (Ni), platinum (Pt), palladium (Pd), vanadium (V), ruthenium (Ru), tantalum (Ta), titanium nitride, titanium silicon nitride, tantalum nitride, tungsten carbonitride, tungsten nitride, molybdenum (Mo), other suitable metal, or combinations thereof. In an exemplary embodiment, the metal layer 260P includes NiPt. The metal layer 260P may include a plurality of layers and may be deposited by ALD, CVD, PVD, and/or other suitable process. In some embodiments, the metal layer 260P is a conformal layer over the workpiece 200. In some embodiments, the metal layer 260P has a thickness of about 5 nm to about 10 nm. If the thickness is too small, such as less than 5 nm, thermal agglomeration and/or discontinuous islanding may cause subsequently formed silicide layers to be non-uniform, thereby having reduced efficacy with respect to reducing contact resistances. If the thickness is too large, such as greater than 10 nm, it may unnecessarily take up valuable space that may be otherwise used by other important features of the transistors.

Referring to FIGS. 28 and 36, method 100′ includes a block 122 where the workpiece 200 is subject to a heating treatment, such as an annealing treatment. In some embodiments, the heating treatment includes annealing the workpiece 200 at a temperature of about 300° C. to about 600° C. In some embodiments, the composition of the ambient gas, the composition of the purge gas, the flow rates of the ambient gas, the flow rate of the purge gas, the gas pressure in the chamber, as well as the temperature ramp-up rate, the temperature hold time, and the temperature range may all be adjusted in order to facilitate the chemical reaction that forms a silicide layer over the p-type source/drain feature 230P. Accordingly, the heating treatment induces a chemical reaction between the p-type source/drain feature 230P and the metal layer 260P. For example, the p-type work function metal of the metal layer 260P reacts with semiconductor atoms in the p-type source/drain feature 230P to form silicide layer 270P. In an exemplary embodiment, the metal layer 260P includes NiPt, and NiPt diffuses into an outer layer of the p-type source/drain feature 230P to react with Si in the p-type source/drain feature 230P. The reaction between NiPt and Si creates a layer of nickel platinum silicon (NiPtSi) as the silicide layer 270P. As a result, a thickness of the p-type source/drain feature 230P (such as along the Z direction) is reduced compared to before the heating treatment. The dashed line 262 represents the top surface of the p-type source/drain feature 230P before the heating treatment, illustrating an outer layer of the p-type source/drain feature 230P is converted to a part of the silicide layer 270P. In some embodiments, the top surfaces of the p-type source/drain feature 230P and the n-type source/drain feature 230N are level before the heating treatment, and the top surface of the p-type source/drain features 230P is below the top surface of the n-type source/drain feature 230N after the heating treatment.

In some embodiments, the silicide layer 270P includes nickel silicon (NiSi), nickel platinum silicon (NiPtSi), other silicide materials, or combinations thereof. In some embodiments, the silicide layer 270P has a thickness of about 5 nm to about 10 nm. If the silicide layer thickness is too small, for example, less than 5 nm, the silicide layer may have limited efficacy in reducing the contact resistances. Furthermore, the silicide may become non-uniform where thermal agglomeration and discontinuous islanding occur. If the silicide layer thickness is too large, such as greater than 10 nm, a large portion of the source/drain material is consumed and may cause issues such as reduced speeds and leakages. After the heating treatment, the portion of the metal layer 260P in direct contact with the p-type source/drain feature 230P is consumed and converted to the silicide layer 270P, while other portions of the metal layer 260P in direction contact with dielectric surfaces of the isolation structure 208 and the CESL 232 do not participate in the chemical reaction. Therefore, the difference in material compositions between the silicide layer 270P and the remaining portions of the metal layer 260P allows the remaining portions of the metal layer 260P to be removed in subsequent processes.

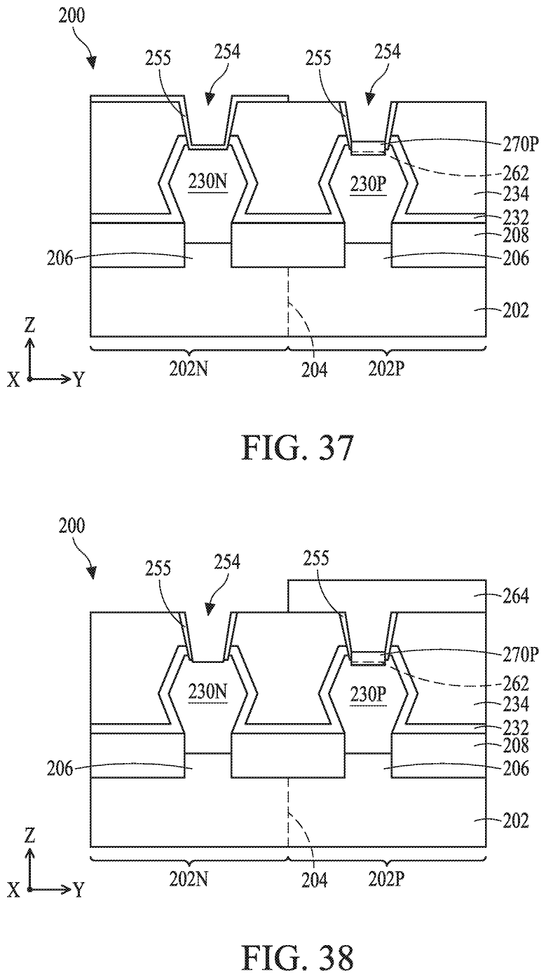

Referring to FIGS. 28 and 37, method 100′ includes a block 124 where an etching process is employed to remove the remaining portions of the metal layer 260P from both the p-type device region 202P and the n-type device region 202N. The etching process is configured to remove the metal layer 260P without substantially etching the silicide layer 270P. In other words, this etching process is a selective etching process. As described above, this may be achieved because of the different material compositions in the silicide layer 270P and the metal layer 260P. Any suitable etching methods may be employed, such as wet etching methods. And any suitable etching chemical may be used. In some embodiments, the etching rate of the metal layer 260P in the etching chemical is at least 10 times greater than the etching rate of the silicide layer 270P in the same etching chemical. Accordingly, the silicide layer 270P is only minimally affected by the etching process. As a result of the etching process, the dielectric liner 255 is exposed in the n-type device region 202N, while the top surface of the p-type source/drain feature 230P remains covered under the silicide layer 270P. Moreover, the silicide layer 270P is exposed in the p-type device region 202P.

Referring to FIGS. 28 and 38, method 100′ includes a block 125 where patterned resist layer 264 is formed to cover and protect the p-type device region 202P and horizontal portions of the dielectric liner 255 are removed from the n-type device region 202N. The n-type device region 202N is exposed in opening of the patterned resist layer 264. The patterned resist layer 264 may be formed by a photolithography process. An exemplary photolithography process may include processing steps of photoresist coating, soft baking, mask aligning, exposing, post-exposure baking, developing photoresist, and hard baking. The photolithography exposing process may also be implemented or replaced by other proper techniques such as maskless photolithography, electron-beam writing, ion-beam writing, and molecular imprint. In some embodiments, the patterned resist layer 264 is a bottom anti-reflective coating (BARC) layer. Subsequently, an etching process is performed for breaking through, and removing the majority of, the horizontal portions of the dielectric liner 255. The etching process is also referred to as a breakthrough (BT) etching process. In some embodiments, the BT etching process may include an anisotropic dry etch process, or the like. In some embodiments where the dielectric liner 255 is formed of an oxide compound, the BT etch process is a reactive ion etch (RIE) process with etch process gases including CHF₃, Ar, CF₄, N₂, O₂, CH₂F₂, SF₃, the like, or a combination thereof. In the illustrated embodiment, as a result of the BT etching process, portions of the dielectric liner 255 remain on sidewalls of the trench 254 in the n-type device region 202N. Moreover, a recessed top surface of the n-type source/drain feature 230N is exposed in the trench 254.

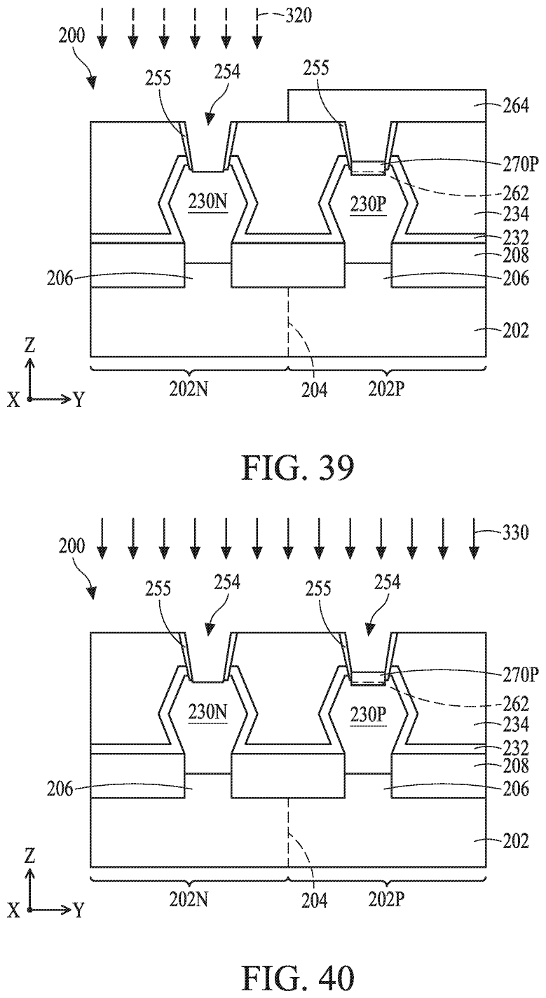

Referring to FIGS. 28 and 39, method 100′ includes a block 128 where an n-type dopant is implanted into the n-type source/drain feature 230N in an implantation process 320. The patterned resist layer 264 acts as an implantation mask to substantially prevent the n-type dopant from being implanted into the p-type device region 202P. The n-type dopant may be phosphorus, arsenic, antimony, or a combination thereof. In some embodiments, the n-type source/drain feature 230N may be in-situ doped with an n-type dopant during the epitaxial process, then the implantation process 320 may be skipped. If the n-type source/drain feature 230N is not in-situ doped, the implantation process 320 (i.e., an ion implantation process) is performed to dope the n-type source/drain feature 230N with suitable n-type dopant. In some embodiments, the n-type source/drain feature 230N may have a dopant concentration of between about 10¹⁹ cm⁻³ and about 10²¹ cm⁻³. In an exemplary embodiment, the source/drain feature 230N after the n-type dopant implantation includes SiP. After the implantation process 320, the patterned resist layer 264 may be removed in a suitable etching process including wet etching, dry etching, reactive ion etching, ashing, and/or other suitable technique.

Referring to FIGS. 28 and 40, method 100′ includes a block 130 where a cleaning process 330 is performed. The cleaning process 330 may include a dry clean, a wet clean, or a combination thereof. In some examples, the wet clean may include use of standard clean 1 (RCA SC-1, a mixture of deionized (DI) water, ammonium hydroxide, and hydrogen peroxide), standard clean 2 (RCA SC-2, a mixture of DI water, hydrochloric acid, and hydrogen peroxide), SPM (a sulfuric peroxide mixture), and/or hydrofluoric acid for oxide removal. The dry clean process may include helium (He) and hydrogen (H₂) treatment at a temperature between about 250° C. and about 550° C. and under a pressure between about 75 mTorr and about 155 mTorr. The hydrogen treatment may convert silicon on the surface to silane (SiH₄), which may be pumped out for removal. The cleaning process 330 may remove surface oxide and debris in order to ensure a clean semiconductor surface, which facilitates growth of silicide structure in subsequent processes.

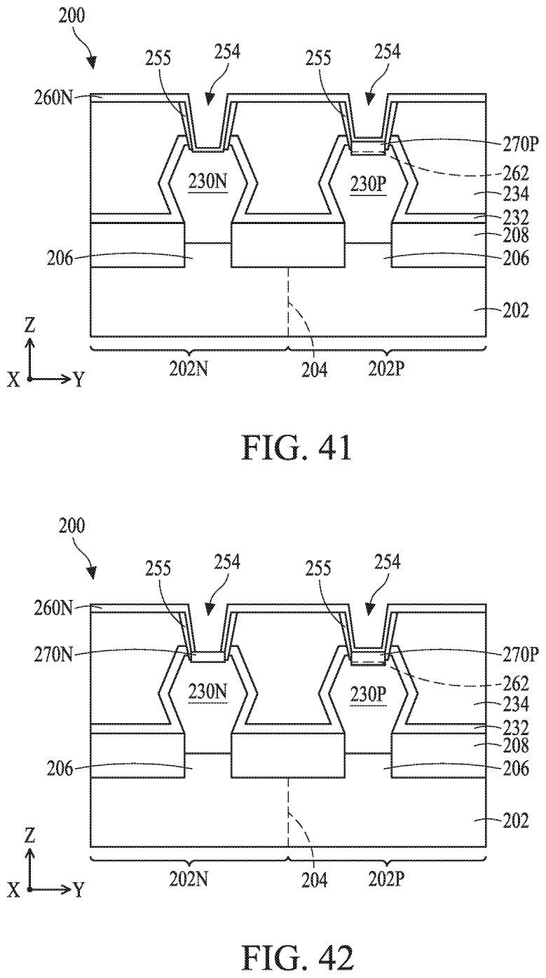

Referring to FIGS. 28 and 41, method 100′ includes a block 132 where a metal layer 260N is formed over the n-type device region 202N and over the p-type device region 202P. The metal layer 260N directly contacts the n-type source/drain feature 230N, and directly contacts the silicide layer 270P over the p-type source/drain feature 230P. In other words, the metal layer 260N does not directly contact (or interface with) the p-type source/drain feature 230P. In some embodiments, the metal layer 260N includes an n-type work function metal. The metal layer 260N may also be referred to as the n-type work function metal layer 260N. N-type work function metals are metals that have work function values less (or lower) than the Fermi level of the semiconductor. The n-type work function metal may be any suitable n-type work function metals, such as titanium (Ti), aluminum (Al), ytterbium (Yb), silver (Ag), TaAl, TaAlC, TiAlN, TaC, TaCN, TaSiN, manganese (Mn), zirconium (Zr), other suitable metal, or combinations thereof. In an exemplary embodiment, the metal layer 260P includes Ti. The metal layer 260N may include a plurality of layers and may be deposited by ALD, CVD, PVD, and/or other suitable process. In some embodiments, the metal layer 260N is a conformal layer over the workpiece 200. In some embodiments, the metal layer 260N has a thickness of about 5 nm to about 10 nm. If the thickness is too small, such as less than 5 nm, thermal agglomeration and/or discontinuous islanding may cause subsequently formed silicide layers to be non-uniform, thereby having reduced efficacy with respect to reducing contact resistances. If the thickness is too large, such as greater than 10 nm, it may unnecessarily take up valuable space that may be otherwise used by other important features of the transistors.

Referring to FIGS. 28 and 42, method 100′ includes a block 134 where the workpiece 200 is subject to a heating treatment, such as an annealing treatment. In some embodiments, the heating treatment includes annealing the workpiece 200 at a temperature of about 300° C. to about 600° C. In some embodiments, the composition of the ambient gas, the composition of the purge gas, the flow rates of the ambient gas, the flow rate of the purge gas, the gas pressure in the chamber, as well as the temperature ramp-up rate, the temperature hold time, and the temperature range may all be adjusted in order to facilitate the chemical reaction that forms a silicide layer over the n-type source/drain feature 230N. Accordingly, the heating treatment induces a chemical reaction between the n-type source/drain feature 230N and the metal layer 260N. For example, the n-type work function metal of the metal layer 260N reacts with semiconductor atoms in the n-type source/drain feature 230N to form silicide layer 270N. In an exemplary embodiment, the metal layer 260N includes Ti, and Si atoms diffuse from the n-type source/drain feature 230N into the metal layer 260N to react with Ti in the metal layer 260N. The reaction between Ti and Si creates a layer of titanium silicon (TiSi) as the silicide layer 270N. Since Si atoms diffuse upwardly into the metal layer 260N, a thickness of the p-type source/drain feature 230P (such as along the Z direction) may be substantially maintained compared to before the heating treatment. That is, the top surface of the p-type source/drain features 230P may be below the top surface of the n-type source/drain feature 230N after the heating treatment, and the top surface of the silicide layer 270P may be below the top surface of the silicide layer 270N.

In some embodiments, the silicide layer 270P includes titanium silicon (TiSi), titanium aluminum silicon (TiAlSi), other silicide materials, or combinations thereof. In some embodiments, the silicide layer 270N has a thickness of about 5 nm to about 10 nm. If the silicide layer thickness is too small, for example, less than 5 nm, the silicide layer may have limited efficacy in reducing the contact resistances. Furthermore, the silicide may become non-uniform where thermal agglomeration and discontinuous islanding occur. If the silicide layer thickness is too large, such as greater than 10 nm, a large portion of the source/drain material is consumed and may cause issues such as reduced speeds and leakages. After the heating treatment, the portion of the metal layer 260N in direct contact with the n-type source/drain feature 230N is consumed and converted to the silicide layer 270N, while other portions of the metal layer 260N in direction contact with dielectric surfaces of the isolation structure 208 and silicide surfaces of the silicide layer 270P do not participate in the chemical reaction. Therefore, the difference in material compositions between the silicide layer 270N and the remaining portions of the metal layer 260N allows the remaining portions of the metal layer 260N to be removed in subsequent processes.

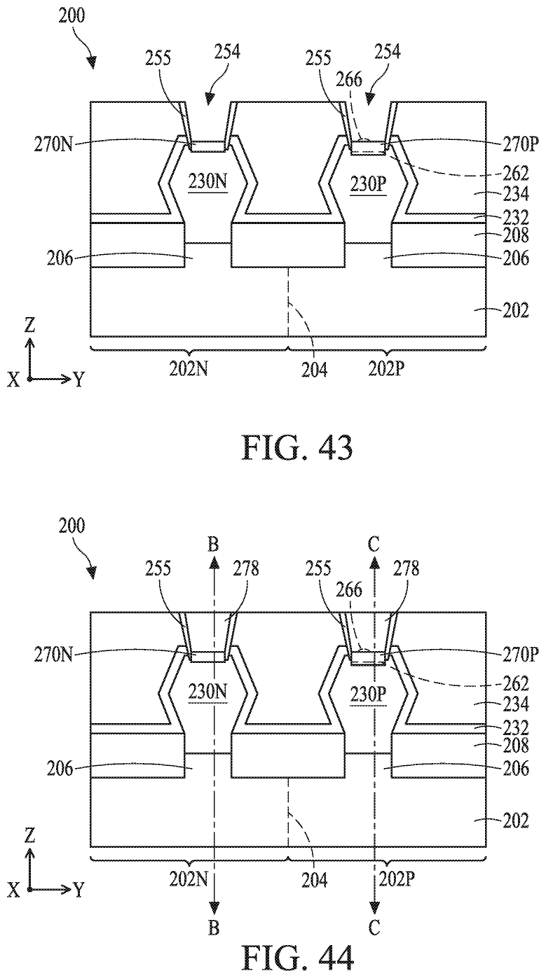

Referring to FIGS. 28 and 43, method 100′ includes a block 136 where an etching process is employed to remove the remaining portions of the metal layer 260N from both the n-type device region 202N and the p-type device region 202P. The etching process is configured to remove the metal layer 260N without substantially etching the silicide layer 270N and the silicide layer 270P. In other words, this etching process is a selective etching process. As described above, this may be achieved because of the different material compositions in the silicide layers 270N, 270P and the metal layer 260N. Any suitable etching methods may be employed, such as wet etching methods. And any suitable etching chemical may be used. In some embodiments, the etching rate of the metal layer 260N in the etching chemical is at least 10 times greater than the etching rate of the silicide layers 270N, 270P in the same etching chemical. Accordingly, the silicide layers 270N, 270P is only minimally affected by the etching process. As a result of the etching process, the silicide layers 270N and 270P are exposed in the n-type device region 202N and the p-type device region 202P, respectively. Further, some residues of the metal layer 260N may remain on the top and sidewall surfaces of the silicide layer 270P. For example, in some embodiments the metal layer 260N includes Ti, and Ti-containing residues may remain as sporadic islands 266 on top surface of the silicide layer 270P.

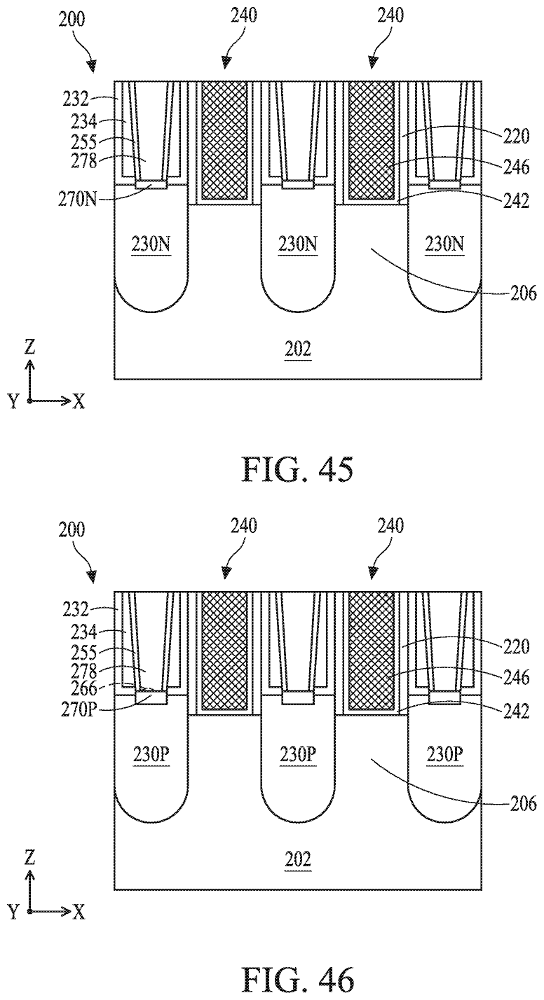

Referring to FIG. 28 and FIGS. 44-46, method 100′ includes a block 138 where source/drain contacts 278 are formed over the silicide layers 270N and 270P. FIG. 45 is a cross-sectional view along the B-B line in FIG. 44, and FIG. 46 is a cross-sectional view along the C-C line in FIG. 44. Particularly, the B-B line is cut along the lengthwise direction of a fin 206 in the n-type device region 202N, and the C-C line is cut along the lengthwise direction of a fin 206 in the p-type device region 202P. The source/drain contacts 278 are formed in the remaining spaces of the trenches 257 such that they are entirely filled. The source/drain contacts 278 may include a conductive barrier layer and a metal fill layer over the conductive barrier layer. The conductive barrier layer may include titanium (Ti), tantalum (Ta), tungsten (W), cobalt (Co), ruthenium (Ru), or a conductive nitride such as titanium nitride (TiN), titanium aluminum nitride (TiAlN), tungsten nitride (WN), tantalum nitride (TaN), or combinations thereof, and may be formed by CVD, PVD, ALD, and/or other suitable processes. The metal fill layer may include tungsten (W), cobalt (Co), molybdenum (Mo), ruthenium (Ru), nickel (Ni), copper (Cu), or other metals, and may be formed by CVD, PVD, ALD, plating, or other suitable processes. In some embodiments, the conductive barrier layer is omitted in the source/drain contacts 278. In some embodiments, a planarization process, such as a CMP process, performed to planarize the top surface of the workpiece 200 and expose the metal gate stacks 240. In the illustrated embodiment, the dielectric liner 255 separates the source/drain contacts 278 from direct contacting with the ILD layer 234. Further, as discussed above, the top surface of the silicide layer 270N may be above the top surface of the silicide layer 270P, and the top surface of the n-type source/drain feature 230N may be above the top surface of the p-type source/drain feature 230P.

Based on the above discussions, it can be seen that the embodiments of the present disclosure offer advantages over conventional technologies for making dual silicide structures. It is understood, however, that no particular advantage is required, other embodiments may offer different advantages, and that not all advantages are necessarily disclosed herein. One advantage is the dual silicide structures allowing the source/drain contact resistance in each of the n-type device region and p-type device region to be optimized individually. Additionally, the processes of the present disclosure are compatible with existing fabrication process flow and are easy and cheap to implement.

In one exemplary aspect, the present disclosure is directed to a method. The method includes forming a first fin in a first device region of a first conductivity type and a second fin in a second device region of a second conductivity type, the first conductivity type being different from the second conductivity type, forming a first epitaxial feature on the first fin and a second epitaxial feature on the second fin, depositing an etch stop layer covering the first epitaxial feature and the second epitaxial feature, removing the etch stop layer from the first device region, depositing a first metal layer over the etch stop layer in the second device region and over and in direct contact with the first epitaxial feature, forming a first silicide layer from the first metal layer and the first epitaxial feature, selectively removing the first metal layer, removing the etch stop layer from the second device region, depositing a second metal layer over the first silicide layer in the first device region and over and in direct contact with the second epitaxial feature, forming a second silicide layer from the second metal layer and the second epitaxial feature, selectively removing the second metal layer, and forming a first contact feature over and in direct contact with the first silicide layer and a second contact feature over and in direct contact with the second silicide layer. In some embodiments, the method further includes depositing an isolation feature between the first epitaxial feature and the second epitaxial feature. The isolation feature has a first sidewall facing the first epitaxial feature and a second sidewall facing the second epitaxial feature, the first contact feature is in direct contact with the first sidewall of the isolation feature, and the second contact feature is in direct contact with the second sidewall of the isolation feature. In some embodiments, the method further includes prior to the removing of the etch stop layer from the first device region, forming a first mask element over the second device region. The first mask element is in direct contact with the second sidewall of the isolation feature, while the first sidewall of the isolation feature is exposed. In some embodiments, the method further includes prior to the removing of the etch stop layer from the second device region, forming a second mask element over the first device region. The second mask element is in direct contact with the first sidewall of the isolation feature, while the second sidewall of the isolation feature is exposed. In some embodiments, the method further includes after the removing of the etch stop layer from the first device region, implanting a first type dopant into the first epitaxial feature, and after the removing of the etch stop layer from the second device region, implanting a second type dopant into the second epitaxial feature. The first type dopant is different from the second type dopant. In some embodiments, the first metal layer includes a p-type work function metal, and the second metal layer includes an n-type work function metal. In some embodiments, the method further includes prior to the depositing of the etch stop layer, depositing an interlayer dielectric layer over the first epitaxial feature and the second epitaxial feature, etching the interlayer dielectric layer to form a first trench exposing a top surface of the first epitaxial feature, and etching the interlayer dielectric layer to form a second trench exposing a top surface of the second epitaxial feature. The etch stop layer is deposited in the first trench and in direct contact with the top surface of the first epitaxial feature and deposited in the second trench and in direct contact with the top surface of the second epitaxial feature. In some embodiments, the method further includes removing horizontal portions of the etch stop layer from the first device region, vertical portions of the etch stop layer remaining on sidewalls of the first trench, and removing horizontal portions of the etch stop layer from the second device region, vertical portions of the etch stop layer remaining on sidewalls of the second trench. In some embodiments, the etch stop layer separates the first and second contact features from directly contacting the interlayer dielectric layer. In some embodiments, a residue of the second metal layer interposes the first silicide layer and the first contact feature.

In another exemplary aspect, the present disclosure is directed to a method. The method includes forming an isolation structure on a substrate, forming a first epitaxial feature in a first device region and a second epitaxial feature in a second device region, the first and second epitaxial features being above the isolation structure, depositing an etch stop layer over and in direct contact with the isolation structure, the first epitaxial feature, and the second epitaxial feature, depositing a dielectric layer over the etch stop layer, etching the dielectric layer to form a trench, depositing an isolation feature in the trench, the isolation feature being positioned between the first epitaxial feature and the second epitaxial feature, removing the dielectric layer, removing the etch stop layer from the first device region to expose the first epitaxial feature, depositing a first metal layer over the etch stop layer in the second device region and over and in direct contact with the first epitaxial feature, the first metal layer including a first type work function metal, forming a first silicide layer from the first metal layer and the first epitaxial feature, removing the etch stop layer from the second device region to expose the second epitaxial feature, depositing a second metal layer over the first silicide layer in the first device region and over and in direct contact with the second epitaxial feature, the second metal layer including a second type work function metal that is different from the first type work function metal, forming a second silicide layer from the second metal layer and the second epitaxial feature, and forming a first contact feature over and in direct contact with the first silicide layer and a second contact feature over and in direct contact with the second silicide layer. In some embodiments, the method further includes after the forming of the first silicide layer, selectively removing the first metal layer, and after the forming of the second silicide layer, selectively removing the second metal layer. In some embodiments, the first metal layer and the second metal layer are in direct contact with the isolation structure. In some embodiments, the first contact feature and the second contact feature are in direct contact with the isolation feature. In some embodiments, the method further includes after the removing of the etch stop layer from the first device region, implanting a first type dopant into the first epitaxial feature, and after the removing of the etch stop layer from the second device region, implanting a second type dopant into the second epitaxial feature, the first type dopant being different from the second type dopant. In some embodiments, the first silicide layer includes NiPtSi, and the second silicide layer includes TiSi.

In yet another exemplary aspect, the present disclosure is directed to a semiconductor device. The semiconductor device includes a first fin protruding from a substrate, the first fin extending lengthwise in a first direction, a second fin protruding from the substrate, the second fin extending lengthwise in the first direction, a first gate stack over the first and second fins, the first gate stack extending lengthwise in a second direction perpendicular to the first direction, a second gate stack over the first and second fins, the second gate stack extending lengthwise in the second direction, a first gate spacer layer disposed on sidewalls of the first gate stack, a second gate spacer layer disposed on sidewalls of the second gate stack, a first epitaxial feature over the first fin and sandwiched between the first and second gate stacks, a first silicide layer over the first epitaxial feature, the first silicide layer including a first type work function metal, a first contact feature over the first silicide layer, a second epitaxial feature over the second fin and sandwiched between the first and second gate stacks, a second silicide layer over the second epitaxial feature, the second silicide layer including a second type work function metal that is different from the first type work function metal, a second contact feature over the second silicide layer, and an isolation feature disposed between the first fin and the second fin. In a top view of the semiconductor device, the isolation feature extends continuously from the first gate spacer layer to the second gate spacer layer along the first direction. In a cross-sectional view of the semiconductor device perpendicular to the first direction, the isolation feature separates the first contact feature from the second contact feature. In some embodiments, a top surface of the first silicide layer is below a top surface of the second silicide layer. In some embodiments, the first contact feature is in direct contact with the first gate spacer layer, and the second contact feature is in direct contact with the second gate spacer layer. In some embodiments, the semiconductor device further includes an isolation structure disposed on sidewalls of the first and second fins. The first and second contact features are in direct contact with the isolation structure.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a first fin in a first device region of a first conductivity type and a second fin in a second device region of a second conductivity type, wherein the first conductivity type is different from the second conductivity type;
forming a first epitaxial feature on the first fin and a second epitaxial feature on the second fin;
depositing an etch stop layer covering the first epitaxial feature and the second epitaxial feature;
removing the etch stop layer from the first device region;
depositing a first metal layer over the etch stop layer in the second device region and over and in direct contact with the first epitaxial feature;
forming a first silicide layer from the first metal layer and the first epitaxial feature;
selectively removing the first metal layer;
removing the etch stop layer from the second device region;
depositing a second metal layer over the first silicide layer in the first device region and over and in direct contact with the second epitaxial feature;
forming a second silicide layer from the second metal layer and the second epitaxial feature;
selectively removing the second metal layer; and
forming a first contact feature over and in direct contact with the first silicide layer and a second contact feature over and in direct contact with the second silicide layer.

2. The method of claim 1, further comprising:
depositing an isolation feature between the first epitaxial feature and the second epitaxial feature,
wherein the isolation feature has a first sidewall facing the first epitaxial feature and a second sidewall facing the second epitaxial feature, the first contact feature is in direct contact with the first sidewall of the isolation feature, and the second contact feature is in direct contact with the second sidewall of the isolation feature.

3. The method of claim 2, further comprising:
prior to the removing of the etch stop layer from the first device region, forming a first mask element over the second device region,
wherein the first mask element is in direct contact with the second sidewall of the isolation feature, while the first sidewall of the isolation feature is exposed.

4. The method of claim 2, further comprising;
prior to the removing of the etch stop layer from the second device region, forming a second mask element over the first device region,
wherein the second mask element is in direct contact with the first sidewall of the isolation feature, while the second sidewall of the isolation feature is exposed.

5. The method of claim 1, further comprising:
after the removing of the etch stop layer from the first device region, implanting a first type dopant into the first epitaxial feature; and
after the removing of the etch stop layer from the second device region, implanting a second type dopant into the second epitaxial feature, wherein the first type dopant is different from the second type dopant.

6. The method of claim 1, wherein the first metal layer includes a p-type work function metal, and the second metal layer includes an n-type work function metal.

7. The method of claim 1, further comprising:
prior to the depositing of the etch stop layer, depositing an interlayer dielectric layer over the first epitaxial feature and the second epitaxial feature;
etching the interlayer dielectric layer to form a first trench exposing a top surface of the first epitaxial feature; and
etching the interlayer dielectric layer to form a second trench exposing a top surface of the second epitaxial feature,
wherein the etch stop layer is deposited in the first trench and in direct contact with the top surface of the first epitaxial feature and deposited in the second trench and in direct contact with the top surface of the second epitaxial feature.

8. The method of claim 7, further comprising:
removing horizontal portions of the etch stop layer from the first device region,
wherein vertical portions of the etch stop layer remain on sidewalls of the first trench; and
removing horizontal portions of the etch stop layer from the second device region, wherein vertical portions of the etch stop layer remain on sidewalls of the second trench.

9. The method of claim 7, wherein the etch stop layer separates the first and second contact features from directly contacting the interlayer dielectric layer.

10. The method of claim 1, wherein a residue of the second metal layer interposes the first silicide layer and the first contact feature.

11. A method, comprising:
forming an isolation structure on a substrate;
forming a first epitaxial feature in a first device region and a second epitaxial feature in a second device region, wherein the first and second epitaxial features are above the isolation structure;
depositing an etch stop layer over and in direct contact with the isolation structure, the first epitaxial feature, and the second epitaxial feature;
depositing a dielectric layer over the etch stop layer;
etching the dielectric layer to form a trench;
depositing an isolation feature in the trench, wherein the isolation feature is positioned between the first epitaxial feature and the second epitaxial feature;
removing the dielectric layer;
removing the etch stop layer from the first device region to expose the first epitaxial feature;
depositing a first metal layer over the etch stop layer in the second device region and over and in direct contact with the first epitaxial feature, wherein the first metal layer includes a first type work function metal;
forming a first silicide layer from the first metal layer and the first epitaxial feature;
removing the etch stop layer from the second device region to expose the second epitaxial feature;
depositing a second metal layer over the first silicide layer in the first device region and over and in direct contact with the second epitaxial feature, wherein the second metal layer includes a second type work function metal that is different from the first type work function metal;
forming a second silicide layer from the second metal layer and the second epitaxial feature; and
forming a first contact feature over and in direct contact with the first silicide layer and a second contact feature over and in direct contact with the second silicide layer.

12. The method of claim 11, further comprising:
after the forming of the first silicide layer, selectively removing the first metal layer; and
after the forming of the second silicide layer, selectively removing the second metal layer.

13. The method of claim 11, wherein the first metal layer and the second metal layer are in direct contact with the isolation structure.

14. The method of claim 11, wherein the first contact feature and the second contact feature are in direct contact with the isolation feature.

15. The method of claim 11, further comprising:
after the removing of the etch stop layer from the first device region, implanting a first type dopant into the first epitaxial feature; and
after the removing of the etch stop layer from the second device region, implanting a second type dopant into the second epitaxial feature, wherein the first type dopant is different from the second type dopant.

16. The method of claim 11, wherein the first silicide layer includes NiPtSi, and the second silicide layer includes TiSi.

17. A semiconductor device, comprising:
a first fin protruding from a substrate, the first fin extending lengthwise in a first direction;
a second fin protruding from the substrate, the second fin extending lengthwise in the first direction;
a first gate stack over the first and second fins, the first gate stack extending lengthwise in a second direction perpendicular to the first direction;
a second gate stack over the first and second fins, the second gate stack extending lengthwise in the second direction;
a first gate spacer layer disposed on sidewalls of the first gate stack;
a second gate spacer layer disposed on sidewalls of the second gate stack;
a first epitaxial feature over the first fin and sandwiched between the first and second gate stacks;
a first silicide layer over the first epitaxial feature, the first silicide layer including a first type work function metal;
a first contact feature over the first silicide layer;
a second epitaxial feature over the second fin and sandwiched between the first and second gate stacks;
a second silicide layer over the second epitaxial feature, the second silicide layer including a second type work function metal that is different from the first type work function metal;
a second contact feature over the second silicide layer; and
an isolation feature disposed between the first fin and the second fin,
wherein in a top view of the semiconductor device, the isolation feature extends continuously from the first gate spacer layer to the second gate spacer layer along the first direction, and
wherein in a cross-sectional view of the semiconductor device perpendicular to the first direction, the isolation feature separates the first contact feature from the second contact feature.

18. The semiconductor device of claim 17, wherein a top surface of the first silicide layer is below a top surface of the second silicide layer.

19. The semiconductor device of claim 17, wherein the first contact feature is in direct contact with the first gate spacer layer, and the second contact feature is in direct contact with the second gate spacer layer.

20. The semiconductor device of claim 17, further comprising:
an isolation structure disposed on sidewalls of the first and second fins,
wherein the first and second contact features are in direct contact with the isolation structure.
